(19) United States
(12) Patent Application Publication
(10) Pub. No.: US 2026/0215147 A1
(43) Pub. Date: Jul. 23, 2026

(54) ORGANOMETALLIC COMPLEX, ORGANIC LIGHT-EMITTING DEVICE, LIGHT-EMITTING COMPOSITION, DISPLAY APPARATUS, IMAGING APPARATUS, ELECTRONIC EQUIPMENT, ILLUMINATION APPARATUS, AND MOVING OBJECT

(71) Applicant: CANON KABUSHIKI KAISHA, Tokyo (JP)

(72) Inventor: AKANE TANAKA, Kanagawa (JP)

(21) Appl. No.: 19/444,033

(22) Filed: Jan. 8, 2026

(30) Foreign Application Priority Data
Jan. 17, 2025 (JP) 2025-006667

(51) Int. Cl. H10K 85/30; C07F 15/00; C09K 11/06; H10K 50/15; H10K 50/16; H10K 85/40

(52) U.S. Cl. CPC H10K 85/361; C07F 15/0086; C09K 11/06; H10K 85/346; H10K 85/40; C09K 2211/1007; C09K 2211/1011; C09K 2211/1029; C09K 2211/1088; C09K 2211/1096; C09K 2211/185; H10K 50/15; H10K 50/16

(57) ABSTRACT

An organometallic complex represented by formula (1).

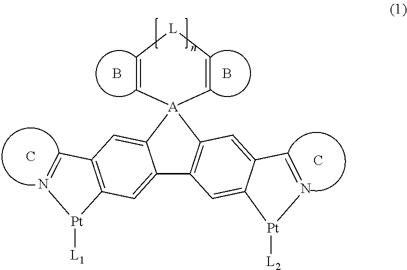

A is a carbon atom or a silicon atom. Each B is independently a substituted or unsubstituted aryl ring or a substituted or unsubstituted heteroaryl ring. L is selected from the group consisting of a carbon atom, a nitrogen atom, an oxygen atom, and a sulfur atom. n is 0 or 1. Each C is a heteroaryl ring, and PtL₁ and PtL₂ are each a bidentate ligand.

### BACKGROUND

### Field of the Technology

The present disclosure relates to an organometallic complex, a light-emitting composition, an organic light-emitting device, a display apparatus, an imaging apparatus, electronic equipment, an illumination apparatus, and a moving object.

### Description of the Related Art

An organic light-emitting device (also referred to as an organic electroluminescent device) is an electronic device including a first electrode, a second electrode, and an organic compound layer disposed between the electrodes. The injection of electrons and holes from this pair of electrodes generates excitons of a light-emitting organic compound in the organic compound layer, and the organic light-emitting device emits light when the excitons return to the ground state. According to the spin-statistics theorem, 75% of the energy of the excitons is triplet energy; therefore, phosphorescent materials, which emit light from the triplet excited state, are known to exhibit high photoluminescence quantum yields. Among such phosphorescent materials, binuclear platinum complexes that have ligands having a structure with high planarity are materials having particularly high photoluminescence quantum yields. The level required for the photoluminescence quantum yields of phosphorescent materials is increasing year by year. To further improve the photoluminescence quantum yields, improvement in the structures of phosphorescent materials has been attempted. J. Mater. Chem. C, 9 (2021) 2282-2290 describes a binuclear platinum complex 1 below.

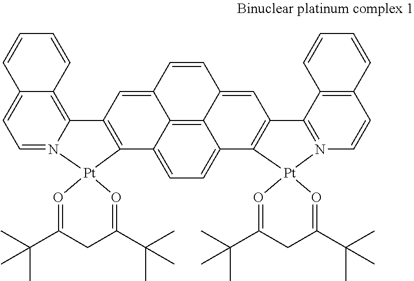

In the binuclear platinum complex 1 described in J. Mater. Chem. C, 9 (2021) 2282-2290, because of its high planarity, the photoluminescence quantum yield is likely to decrease due to the formation of a trap site and concentration quenching. When the binuclear platinum complex 1 is used in a light-emitting layer of an organic light-emitting device, the above disadvantage is particularly likely to occur under the conditions of high doping concentrations.

### SUMMARY

In view of the foregoing, the present disclosure is directed to providing an organometallic complex in which a decrease in the photoluminescence quantum yield due to the formation of a trap site and concentration quenching is reduced.

The present disclosure provides an organometallic complex represented by formula (1).

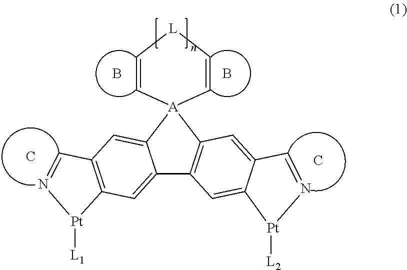

In formula (1), A is a carbon atom or a silicon atom.

Each B is independently a substituted or unsubstituted aryl ring or a substituted or unsubstituted heteroaryl ring.

L is selected from the group consisting of a carbon atom, a nitrogen atom, an oxygen atom, and a sulfur atom. n is 0 or 1.

Each C is independently a substituted or unsubstituted heteroaryl ring, and PtL₁ and PtL₂ are each independently a bidentate ligand represented by formula (3).

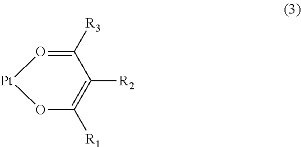

In formula (3), R₁ to R₃ are each independently selected from the group consisting of a hydrogen atom, a deuterium atom, a halogen atom, a substituted or unsubstituted alkyl group, a substituted or unsubstituted cycloalkyl group, a substituted or unsubstituted alkoxy group, a substituted or unsubstituted aryl group, and a substituted or unsubstituted heteroaryl group.

Features of the present disclosure will become apparent from the following description of embodiments with reference to the attached drawings. The following description of embodiments is described by way of example.

### BRIEF DESCRIPTION OF THE DRAWINGS

FIG. 1A is a schematic sectional view illustrating an example of a pixel of a display apparatus according to an embodiment of the present disclosure. FIG. 1B is a schematic sectional view illustrating an example of a display apparatus using an organic light-emitting device according to an embodiment of the present disclosure.

FIG. 2 is a schematic view illustrating an example of a display apparatus according to an embodiment of the present disclosure.

FIG. 3A is a schematic view illustrating an example of an imaging apparatus according to an embodiment of the present disclosure. FIG. 3B is a schematic view illustrating an example of electronic equipment according to an embodiment of the present disclosure.

FIG. 4A is a schematic view illustrating an example of a display apparatus according to an embodiment of the present disclosure. FIG. 4B is a schematic view illustrating an example of a foldable display apparatus.

FIG. 5A is a schematic view illustrating an example of an illumination apparatus according to an embodiment of the present disclosure. FIG. 5B is a schematic view illustrating an example of an automobile including a vehicle lighting fixture according to an embodiment of the present disclosure.

FIG. 6A is a schematic view illustrating an example of a wearable device according to an embodiment of the present disclosure. FIG. 6B is a schematic view illustrating an example of the wearable device according to an embodiment of the present disclosure, the wearable device including an imaging apparatus.

### DESCRIPTION OF THE EMBODIMENTS

The present disclosure will be described in detail with reference to preferred embodiments below. The present disclosure is not limited to the description below, and a person skilled in the art can easily understand that various modifications in the forms and details can be made without departing from the spirit and the scope of the present disclosure. That is, the present disclosure is not construed as being limited by the following description.

### Organometallic Complex

An organometallic complex according to the present disclosure is represented by a general formula (1) below or a general formula (2) below.

In the general formula (1), rings B in the organometallic complex are each independently selected from the group consisting of a substituted or unsubstituted aryl ring and a substituted or unsubstituted heteroaryl ring. In the general formula (2), rings D are each a substituted or unsubstituted aryl ring or a substituted or unsubstituted heteroaryl ring. That is, specific positions are substituted with aromatic substituents; therefore, aggregation of the organometallic complex can be reduced by the large molecular volume. Furthermore, since the utilization efficiency of exciton energy is improved by the π-π interaction between the molecules, a decrease in the photoluminescence quantum yield of the organometallic complex at a high doping concentration is suppressed.

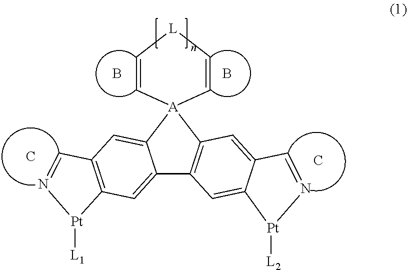

In the general formula (1), A is selected from the group consisting of a carbon atom and a silicon atom. Rings B are each independently a substituted or unsubstituted aryl ring or a substituted or unsubstituted heteroaryl ring, and L is selected from a carbon atom, a nitrogen atom, an oxygen atom, and a sulfur atom. When L is a carbon atom or a nitrogen atom, the carbon atom or the nitrogen atom may have a substituent. n is 0 or 1. Rings C are each independently a substituted or unsubstituted heteroaryl ring, and PtL₁ and PtL₂ are each independently a bidentate ligand represented by a general formula (3) below.

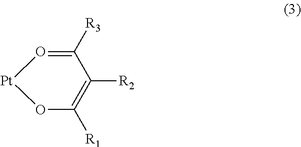

In the general formula (3), R₁ to R₃ are each independently selected from the group consisting of a hydrogen atom, a deuterium atom, a halogen atom, a substituted or unsubstituted alkyl group, a substituted or unsubstituted cycloalkyl group, a substituted or unsubstituted alkoxy group, a substituted or unsubstituted aryl group, and a substituted or unsubstituted heteroaryl group.

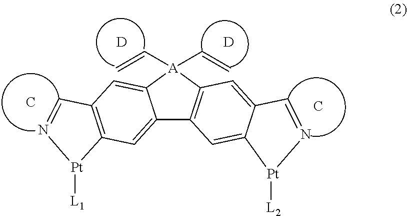

In the general formula (2), A is selected from the group consisting of a carbon atom and a silicon atom. Rings C are each independently selected from the group consisting of a substituted or unsubstituted heteroaryl ring, rings D are each independently selected from the group consisting of a substituted or unsubstituted aryl ring and a substituted or unsubstituted heteroaryl ring, and PtL₁ and PtL₂ are each independently a bidentate ligand represented by the general formula (3).

In the general formula (1), the rings B are each independently selected from the group consisting of a substituted or unsubstituted aryl ring and a substituted or unsubstituted heteroaryl ring.

In the general formula (1), the rings B are each independently selected from the group consisting of a substituted or unsubstituted aryl ring and a substituted or unsubstituted heteroaryl ring. The aryl ring in each of the rings B may be an aryl ring having 6 to 30 carbon atoms and may be a monocyclic ring or a fused ring. In particular, the aryl ring of the ring B in the general formula (1) is preferably a benzene ring, a naphthalene ring, a fluorene ring, a phenanthrene ring, a 9,9-spirobifluorene ring, or a chrysene ring. The heteroaryl ring in each of the rings B may be a heteroaryl ring having 6 to 30 carbon atoms and may be a monocyclic ring or a fused ring. In particular, the heteroaryl ring of the ring B in the general formula (1) is preferably a pyridine ring, a dibenzofuran ring, a dibenzothiophene ring, or a carbazole ring. The substituents that the ring B may have represent a halogen atom, an alkyl group, a cycloalkyl group, an alkoxy group, an aryl group, a heteroaryl group, an aryloxy group, a heteroaryloxy group, a silyl group, an alkoxycarbonyl group, an acyl group, and a cyano group.

The halogen atom may be, for example, a fluorine atom, a chlorine atom, a bromine atom, or an iodine atom. In particular, in view of thermal stability, a fluorine atom is preferred.

The alkyl group may be a linear or branched alkyl group having 1 to 30 carbon atoms, preferably 1 to 20 carbon atoms, more preferably 1 to 6 carbon atoms. Specific examples of the alkyl group include a methyl group, an ethyl group, a n-propyl group, an i-propyl group, a n-butyl group, a tert-butyl group, a sec-butyl group, and an octyl group. The alkyl group may have a substituent as long as the photoluminescence quantum yield is not impaired. Examples of such a substituent include a halogen atom, a cyano group, and a nitro group. Furthermore, one methylene group or two or more non-adjacent methylene groups of the alkyl group may be substituted with —O—, —S—, —C(═O)—, —C(═O)O—, —O (C═O)—, —CH═CH—, or —C═C—.

The cycloalkyl group may be a cycloalkyl group having 3 to 30 carbon atoms, preferably 3 to 20 carbon atoms, more preferably 3 to 6 carbon atoms. Specific examples of the cycloalkyl group include a cyclopropyl group and a cyclohexyl group. The cycloalkyl group may have a substituent as long as the photoluminescence quantum yield is not impaired. Examples of such a substituent include a halogen atom, a cyano group, and a nitro group.

The alkoxy group may be an alkoxy group having 1 to 20 carbon atoms, preferably 1 to 6 carbon atoms. Specific examples of the alkoxy group include a methoxy group, an ethoxy group, a propoxy group, and a 2-ethyl-octyloxy group. The alkoxy group may have a substituent as long as the photoluminescence quantum yield is not impaired. Examples of such a substituent include a halogen atom, a cyano group, a nitro group, a benzyl group, and a naphthyl group. The halogen atom may be the same as that described as the halogen atom among the substituents that the ring B in the general formula (1) may have.

The aryl group may be an aryl group having 6 to 30 carbon atoms and may be a monocyclic ring or a fused ring. Specific examples of the aryl group include a phenyl group, a naphthyl group, a fluorenyl group, a phenanthrenyl group, an anthracenyl group, a carbazolyl group, a dibenzofuryl group, and a dibenzothienyl group. The aryl group may have a substituent as long as the photoluminescence quantum yield is not impaired. Examples of such a substituent include a halogen atom, a cyano group, a nitro group, an alkyl group, an alkoxy group, a benzyl group, a naphthyl group, and combinations thereof. The halogen atom, the alkyl group, and the alkoxy group may be the same as those described as the groups among the substituents that the ring B in the general formula (1) may have.

The heteroaryl group may be a heteroaryl group having 3 to 15 atoms constituting the ring and may be a monocyclic ring or a fused ring. Examples of the heteroatom include a nitrogen atom, an oxygen atom, a sulfur atom, a silicon atom, a phosphorus atom, and a germanium atom. A plurality of atoms selected from these heteroatoms may be contained. Specific examples of the heteroaryl group include a pyridyl group, a pyrimidyl group, a pyrazyl group, a triazyl group, a benzofuranyl group, a benzothiophenyl group, a dibenzofuranyl group, a dibenzothiophenyl group, an oxazolyl group, an oxadiazolyl group, a thiazolyl group, a thiadiazolyl group, a carbazolyl group, an acridinyl group, and a phenanthrolyl group. The heteroaryl group may have a substituent as long as the photoluminescence quantum yield is not impaired. Examples of such a substituent include a halogen atom, a cyano group, a nitro group, an alkyl group, an alkoxy group, a benzyl group, a naphthyl group, and combinations thereof. The halogen atom, the alkyl group, and the alkoxy group may be the same as those described as the groups among the substituents that the ring B in the general formula (1) may have.

The aryloxy group may be an aryloxy group having an aryl moiety with 6 to 30 carbon atoms. Specific examples of the aryloxy group include a phenoxy group and a naphthoxy group. The aryloxy group may be substituted with a halogen atom, a cyano group, an alkyl group, or an alkoxy group. The halogen atom, the alkyl group, and the alkoxy group may be the same as those described as the groups among the substituents that the ring B in the general formula (1) may have.

The heteroaryloxy group may be a heteroaryloxy group having 3 to 15 atoms constituting the ring of the heteroaryl moiety and may be a monocyclic ring or a fused ring. The heteroatom may be the same as that described as the heteroatom of the heteroaryl group among the substituents that the ring B in the general formula (1) may have. Specific examples of the heteroaryloxy group include a pyridyloxy group, a pyrimidyloxy group, a pyrazyloxy group, a triazyloxy group, a benzofuryloxy group, a dibenzofuryloxy group, a benzothienyloxy group, a dibenzothienyloxy group, a pyrrolyloxy group, an indolyloxy group, and an N-methylcarbazolyloxy group.

The silyl group is a group in which an alkyl group, an aryl group, or an alkoxy group is bonded to a silicon atom. The silyl group may be, for example, a trialkylsilyl group, a dialkylarylsilyl group, an alkyldiarylsilyl group, or a triarylsilyl group. Among these, a silyl group substituted with an alkyl group having 1 to 8 carbon atoms or an aryl group having 6 to 10 carbon atoms is preferred. Specific examples thereof include a trimethylsilyl group, a triphenylsilyl group, a tert-butyldimethylsilyl group, a triisopropylsilyl group, and a tert-butyldiphenylsilyl group.

The acyl group may be an acyl group having 1 to 20 carbon atoms. Specific examples of the acyl group include a formyl group, an acetyl group, a propionyl group, and a benzoyl group.

The alkoxycarbonyl group may be an alkoxycarbonyl group having 2 to 20 carbon atoms. Specific examples of the alkoxycarbonyl group include a methoxycarbonyl group, an ethoxycarbonyl group, and a hexyloxycarbonyl group.

In the general formula (1), L is selected from a carbon atom, a nitrogen atom, an oxygen atom, and a sulfur atom. When L is a carbon atom or a nitrogen atom, the carbon atom or the nitrogen atom may have a substituent. The substituent is selected from a linear or branched alkyl group having 1 to 6 carbon atoms, a fluorine atom, a silyl group, an aryl group, and a heteroaryl group.

Specifically, the alkyl group serving as the substituent of L may be a methyl group, an ethyl group, a n-propyl group, an i-propyl group, a n-butyl group, a tert-butyl group, or a sec-butyl group. Among these, a methyl group, an i-propyl group, or a tert-butyl group is preferred.

The aryl group serving as the substituent of L may be the same as that described as the aryl group among the substituents that the ring B in the general formula (1) may have. Among these, a phenyl group or a trimethylphenyl group is preferred.

The heteroaryl group serving as the substituent of L may be the same as that described as the heteroaryl group among the substituents that the ring B in the general formula (1) may have. Among these, a carbazolyl group is preferred.

In the general formula (1), n is 0 or 1. When n is 0, it is indicated that the rings B are directly bonded to each other. In order to further suppress the decrease in the photoluminescence quantum yield of the organometallic complex at a high doping concentration, n is preferably 0 in view of the rigidity of the ligand.

In the general formulas (1) and (2), rings C are each a substituted or unsubstituted heteroaryl ring. When a plurality of such heteroaryl groups are present, the heteroaryl groups may be the same or different.

The rings C are each bonded to a Pt atom via one N atom. Each of the rings C is a substituted or unsubstituted heteroaryl ring and may be the same as that described as the ring B in the general formula (1). Among these, a pyridine ring, a pyrazine ring, a pyrimidine ring, a pyrrole ring, a pyrazole ring, a triazole ring, or a benzoquinoline ring is preferred.

The substituent that each of the rings C may have is selected from a linear or branched alkyl group having 1 to 6 carbon atoms, a fluorine atom, a silyl group, an aryl group, and a heteroaryl group, and may be a combination thereof. The substituents that are adjacent to each other may be bonded together.

Specifically, the alkyl group serving as the substituent of the ring C may be a methyl group, an ethyl group, a n-propyl group, an i-propyl group, a n-butyl group, a tert-butyl group, or a sec-butyl group. Among these, a methyl group, an i-propyl group, or a tert-butyl group is preferred.

The aryl group serving as the substituent of the ring C may be the same as that described as the aryl group among the substituents that the ring B in the general formula (1) may have. Among these, a phenyl group or a trimethylphenyl group is preferred.

The heteroaryl group serving as the substituent of the ring C may be the same as that described as the heteroaryl group among the substituents that the ring B in the general formula (1) may have. Among these, a carbazolyl group is preferred.

In the general formula (2), the rings D are each independently selected from a substituted or unsubstituted aryl ring and a substituted or unsubstituted heteroaryl ring. The aryl ring and the heteroaryl ring may be the same as those described as the ring B in the general formula (1).

Among these, a phenyl group, a naphthalene group, a dibenzofuranyl group, or a dibenzothiophenyl group is preferred.

In the general formulas (1) and (2), PtL₁ and PtL₂ are each a bidentate ligand represented by the general formula (3). In the general formula (3), R₁ to R₃ are each independently selected from a hydrogen atom, a deuterium atom, a halogen atom, a substituted or unsubstituted alkyl group, a substituted or unsubstituted cycloalkyl group, a substituted or unsubstituted alkoxy group, a substituted or unsubstituted aryl group, and a substituted or unsubstituted heteroaryl group. The halogen atom, the alkyl group, the cycloalkyl group, the alkoxy group, the aryl group, and the heteroaryl group represented by R₁ to R₃ may be the same as those described as the groups among the substituents that the ring B in the general formula (1) may have. In particular, in view of thermal stability, R₁ and R₃ are each preferably the above alkyl group.

Specific examples of the compound represented by the general formula (1) and the compound represented by the general formula (2) are shown below. As a matter of course, in the present disclosure, the compounds are not limited to the specific examples below as long as they are included in the definitions of the general formulas (1) and (2).

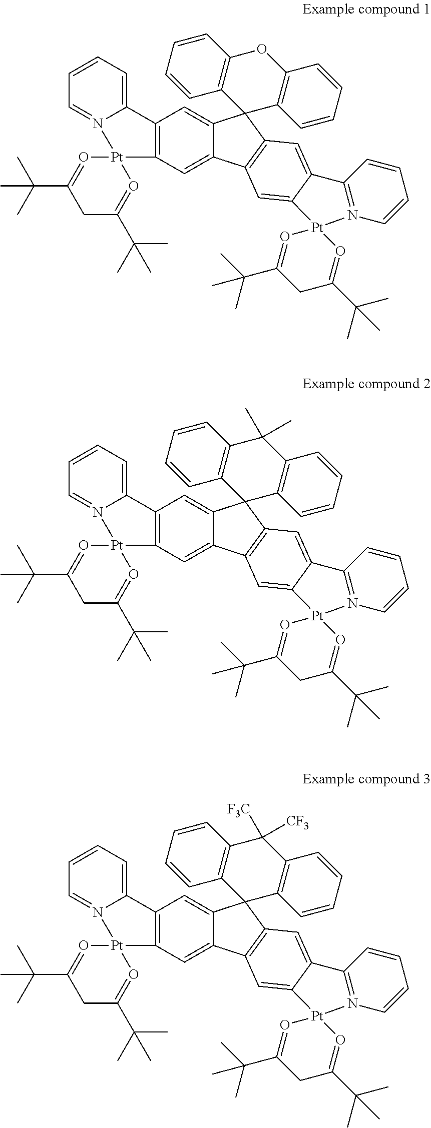

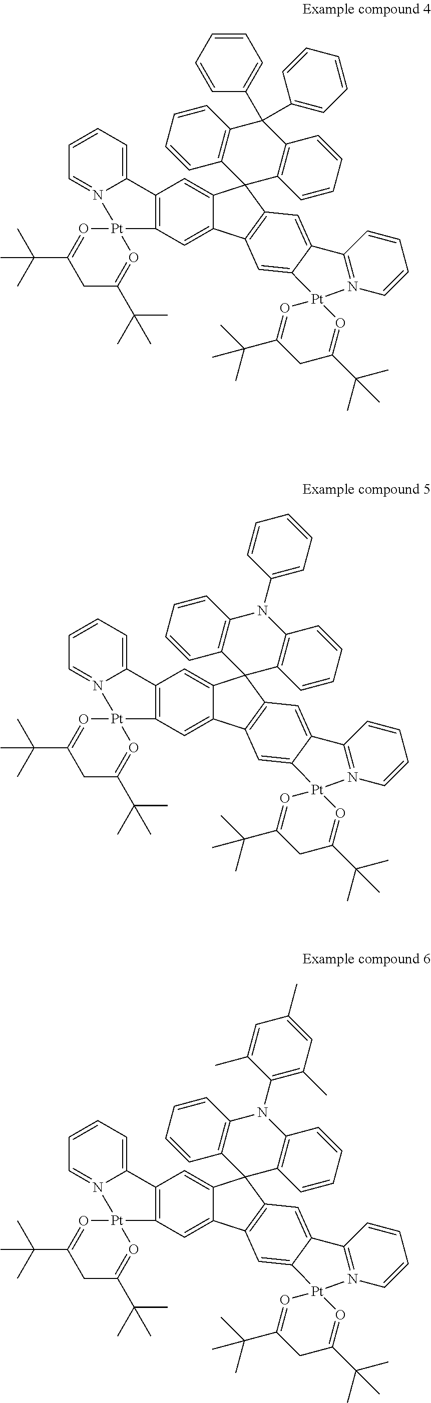

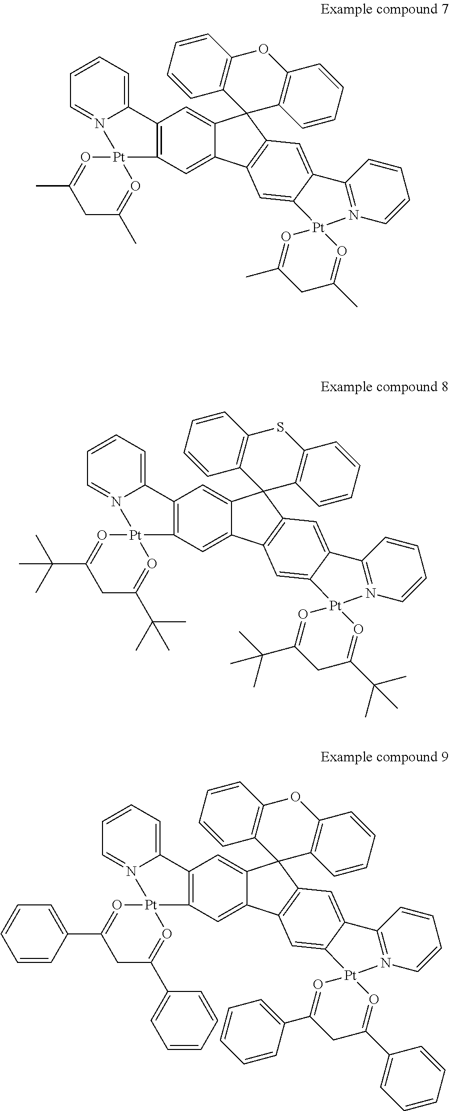

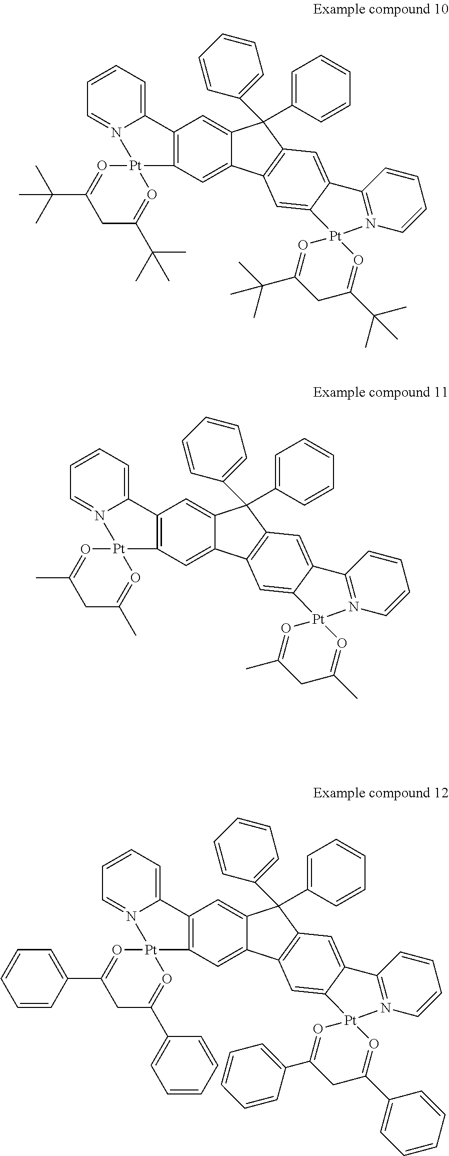

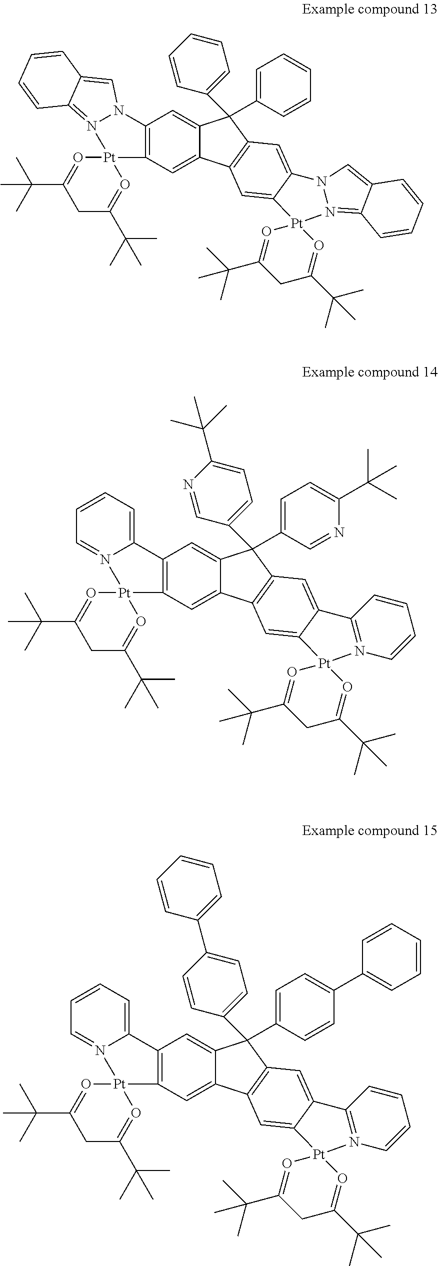

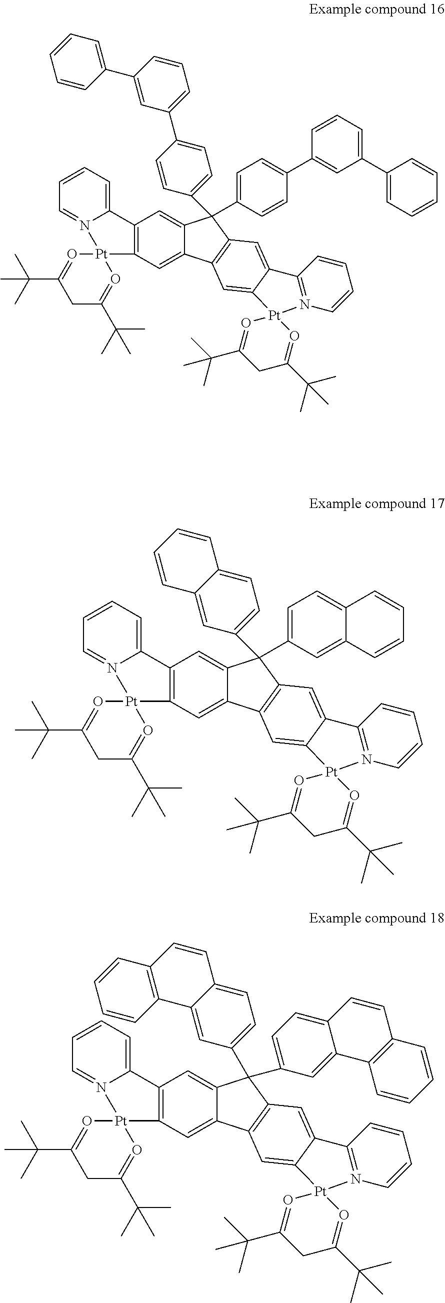

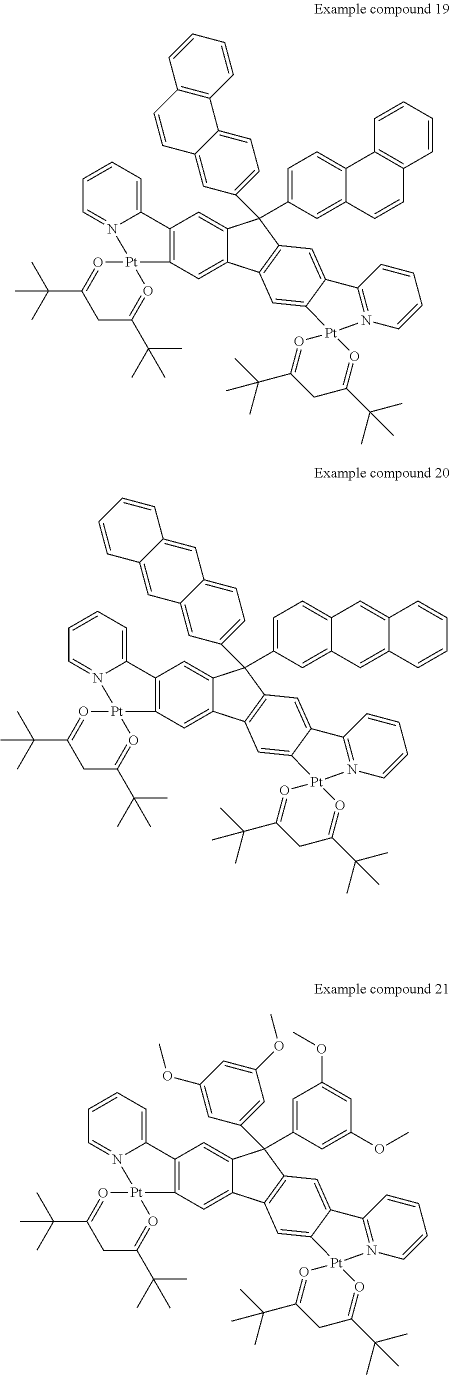

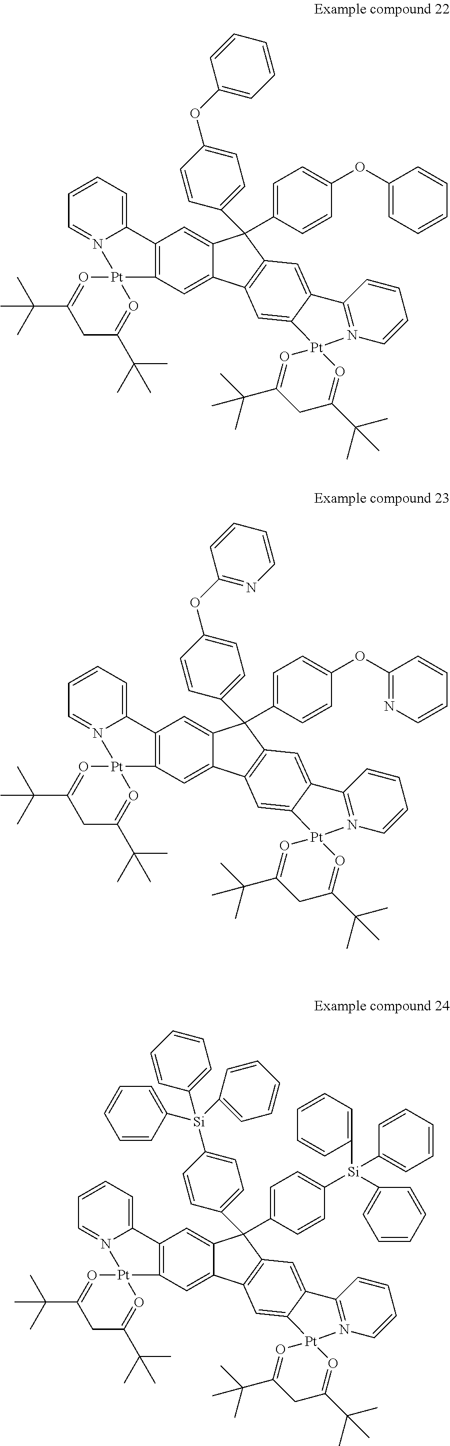

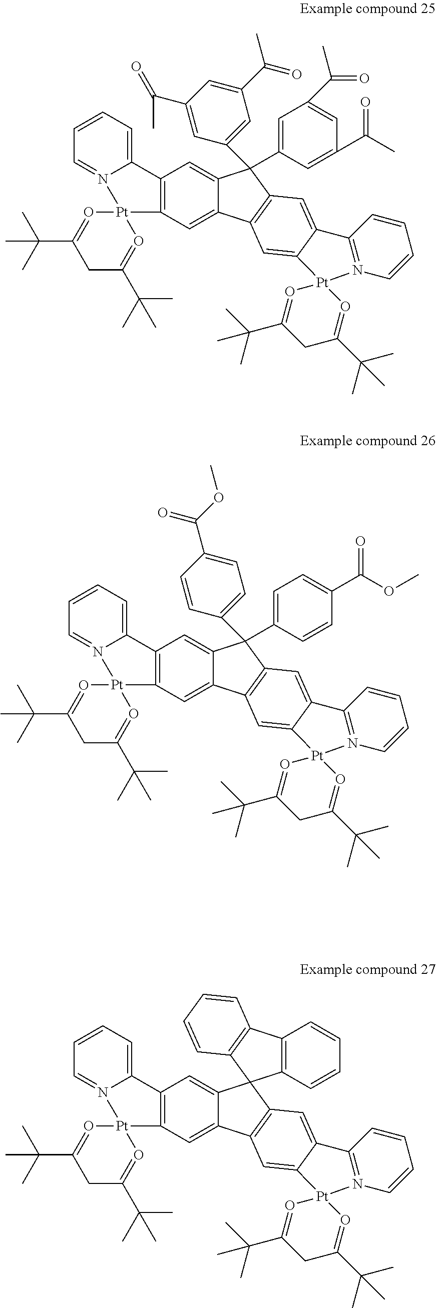

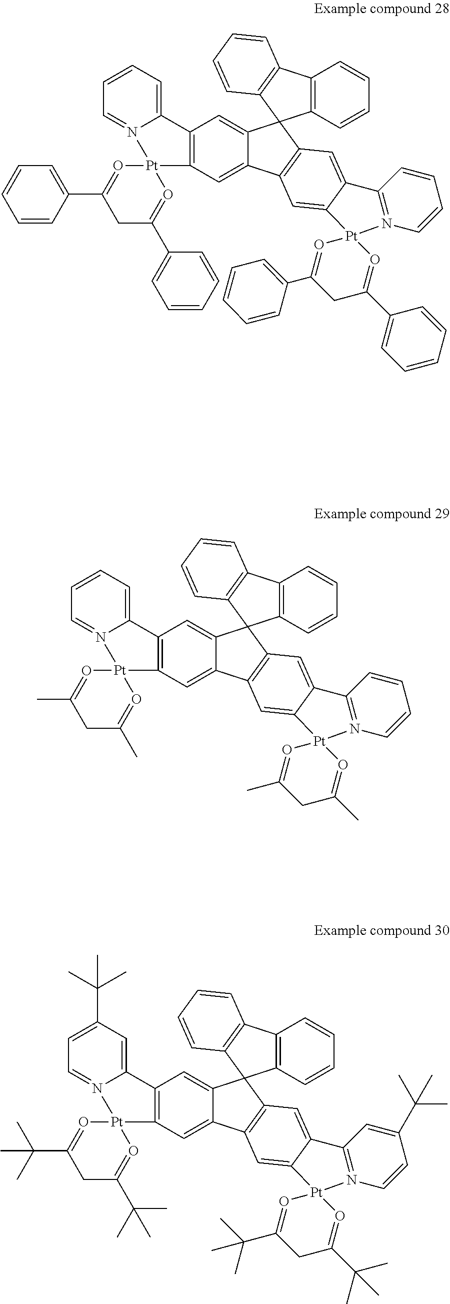

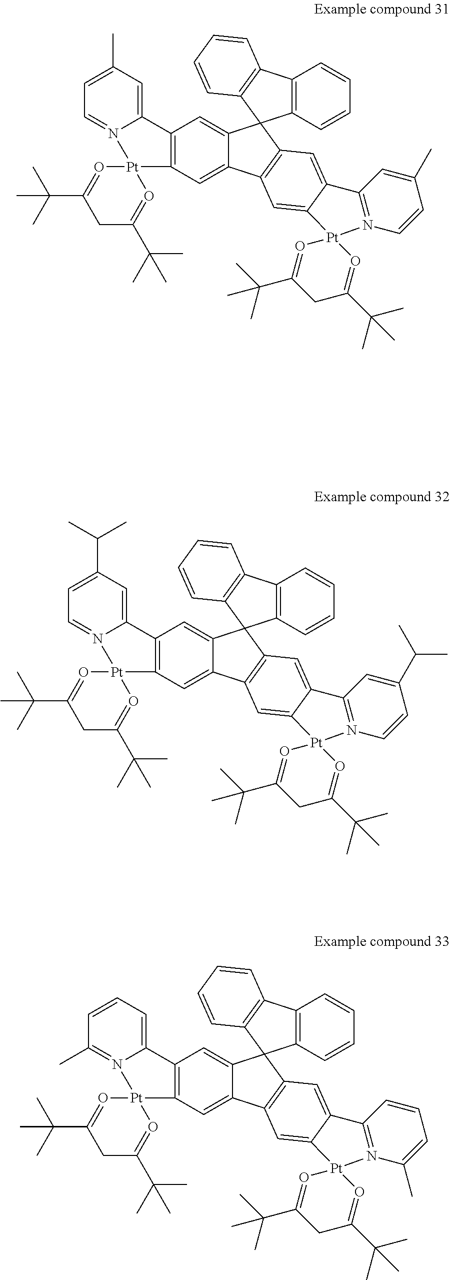

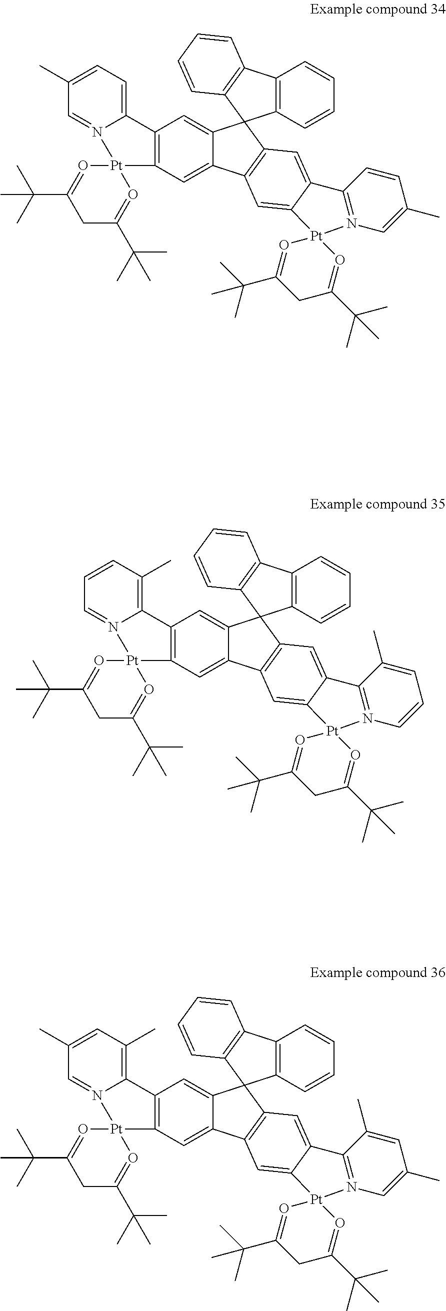

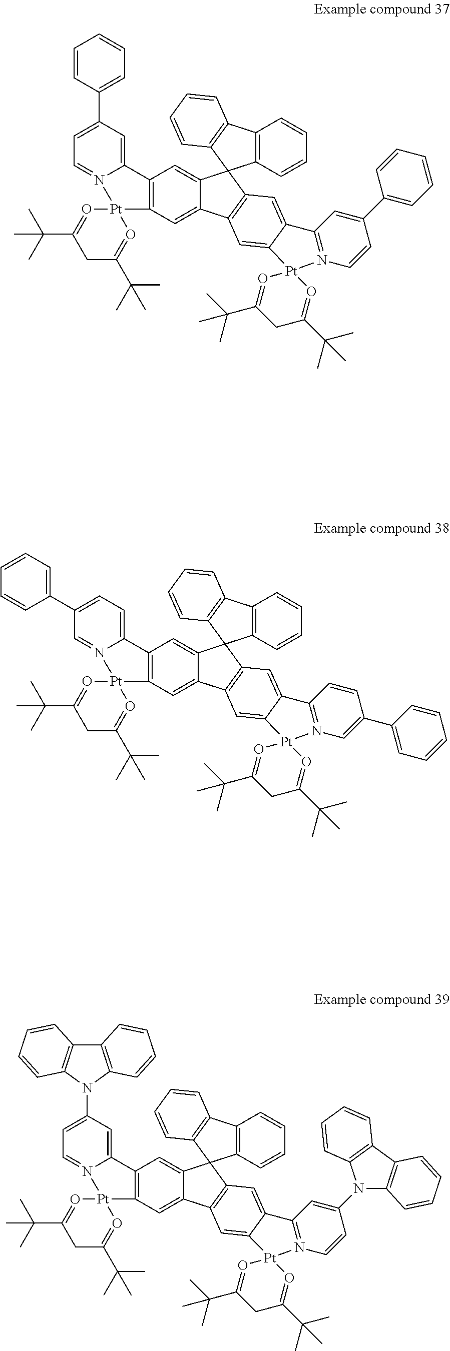

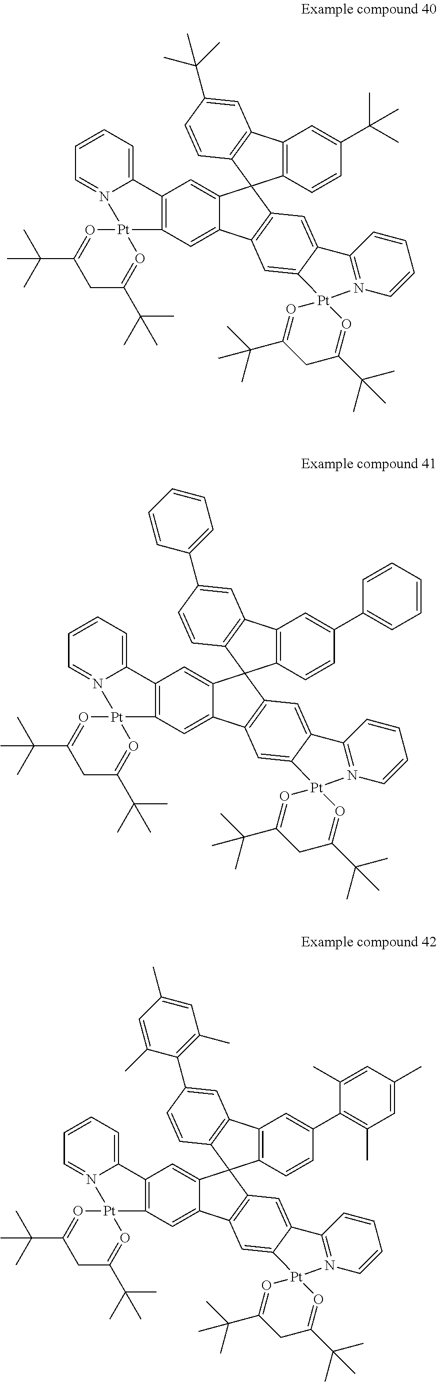

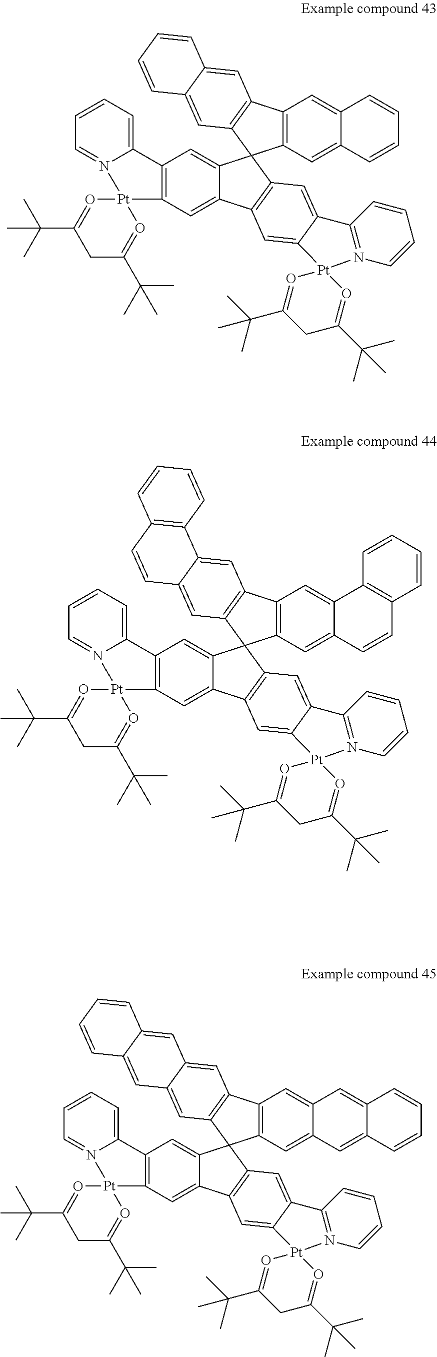

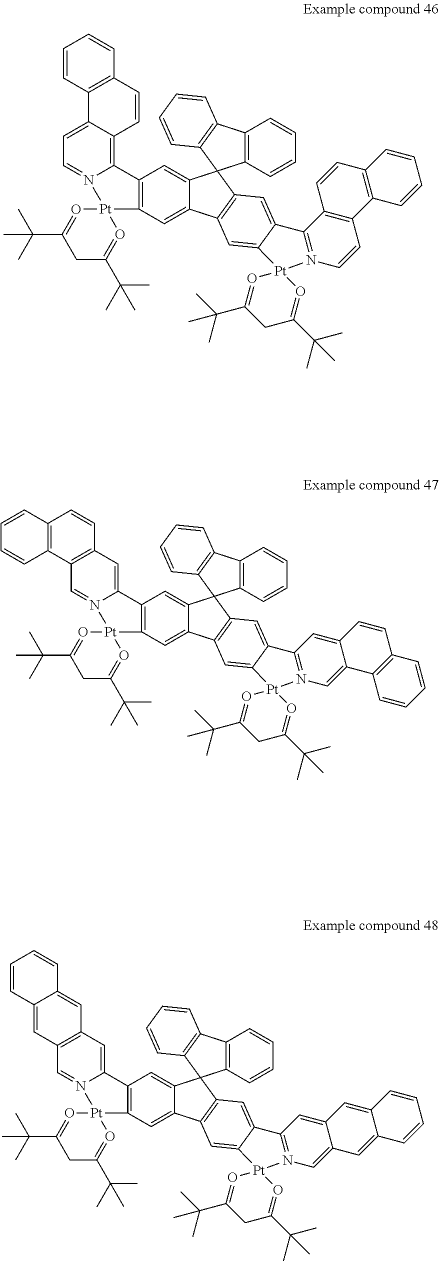

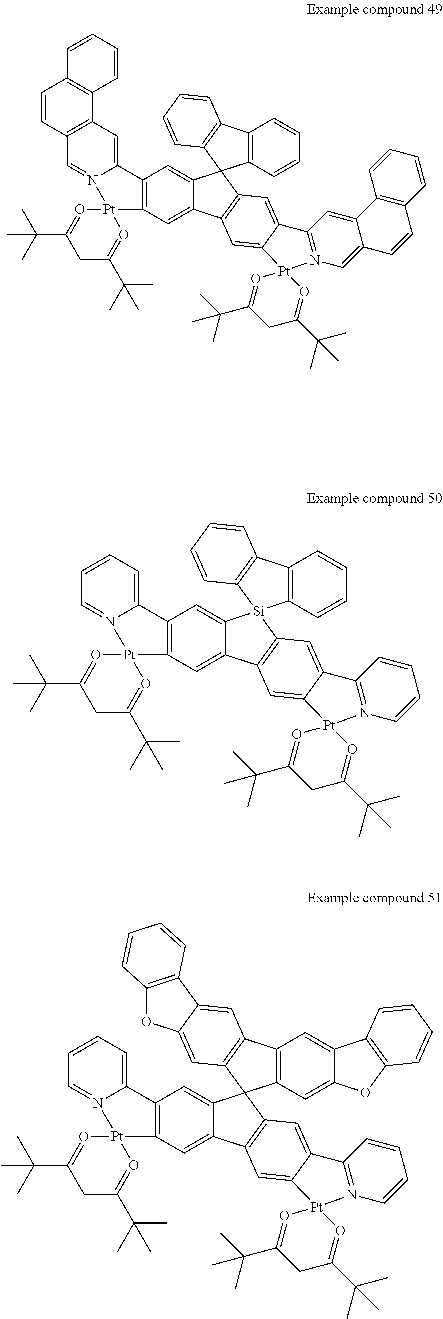

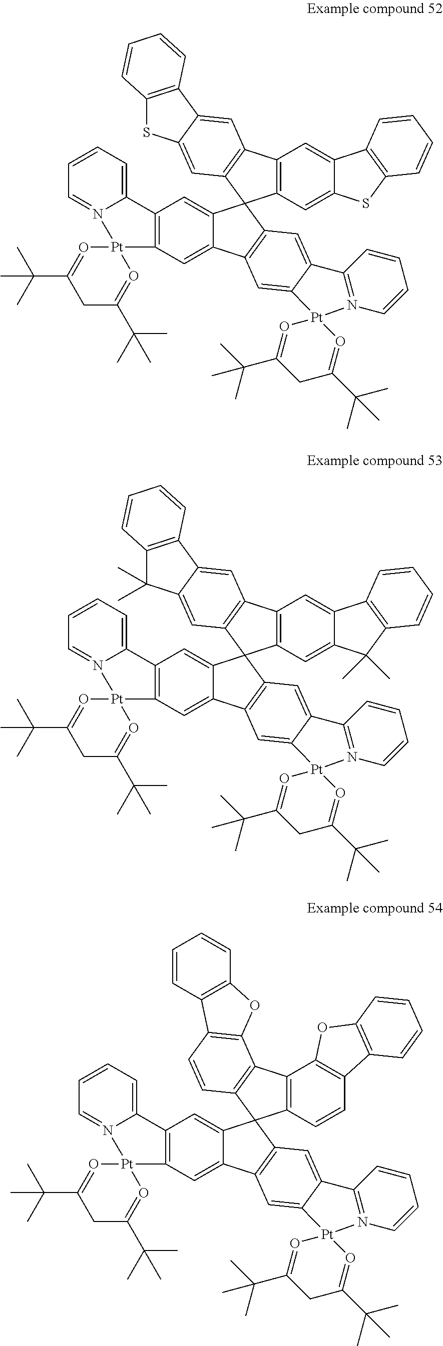

### Structure of Organic Light-Emitting Device

An organic light-emitting device may have a structure in which an insulating layer, a first electrode, an organic compound layer, and a second electrode are stacked in this order on a substrate. A protective layer, a color filter, and the like may be disposed on the second electrode (in the direction opposite to the substrate). When a color filter is provided, a planarization layer may be disposed between the color filter and the protective layer. One of the first electrode and the second electrode is an anode, and the other is a cathode.

### Substrate

The substrate used may be formed of quartz, glass, silicon, a resin, a metal, or the like. A switching element such as a transistor, wiring, and the like, may be disposed on the substrate, and an insulating layer may be disposed thereon. The insulating layer used may be formed of any material as long as a contact hole can be formed to ensure electrical connection between the anode and wiring and the insulating layer is insulated from wiring not to be connected. Specifically, the insulating layer may be formed of, for example, a resin, such as a polyimide, or a silicon compound, such as silicon oxide or silicon nitride.

### Electrodes

An organic light-emitting device is provided with a pair of electrodes. The pair of electrodes are an anode and a cathode. When a voltage is applied in a direction in which the organic light-emitting device emits light, an electrode with a high electric potential is the anode, and the other electrode is the cathode. In other words, the electrode that supplies holes to the light-emitting layer is the anode, and the electrode that supplies electrons to the light-emitting layer is the cathode.

The constituent material of the anode preferably has a large work function. Examples thereof include metals such as gold, platinum, silver, copper, nickel, palladium, cobalt, selenium, vanadium, and tungsten; metal oxides such as tin oxide, zinc oxide, indium oxide, indium tin oxide (ITO), and indium zinc oxide; mixtures and alloys thereof; and electrically conductive polymers such as polyaniline, polypyrrole, and polythiophene. The constituent materials of the electrode may be used alone or in combination of two or more thereof. The anode may be composed of one or two or more layers.

The constituent material of the anode used as a reflective electrode may be, for example, a metal such as chromium, aluminum, silver, titanium, tungsten, or molybdenum; or an alloy or laminate thereof. A constituent material of the anode used as a transparent electrode may be an oxide such as indium tin oxide (ITO) or indium zinc oxide. The anode may be formed by photolithography.

On the other hand, the constituent material of the cathode preferably has a small work function. Examples thereof include alkali metals such as lithium; alkaline earth metals such as calcium; other metals such as aluminum, titanium, manganese, silver, lead, and chromium; oxides, mixtures, and alloys thereof. Examples of the alloys include magnesium-silver, aluminum-lithium, aluminum-magnesium, silver-lithium, silver-copper, and zinc-silver. The constituent material of the cathode may be a metal oxide such as indium tin oxide (ITO). The constituent materials of the electrode may be used alone or in combination of two or more thereof. The cathode may be composed of one or two or more layers. In particular, silver is preferably used, and a silver alloy is more preferably used to suppress the aggregation of silver. The alloy may have any ratio as long as the aggregation of silver can be suppressed. For example, the ratio may be 1:1.

The cathode may be a conductive oxide layer made of indium tin oxide (ITO) or the like to provide a top-emission device. Alternatively, the cathode may be a reflective electrode made of aluminum (Al) or the like to provide a bottom-emission device. The cathode may also be formed by photolithography. In particular, a method for forming the cathode is preferably a sputtering method (direct current or alternating current). This is because a film formed by the sputtering method has good coverage and thus the resistance is easily reduced.

### Protective Layer

A protective layer can be disposed on a cathode. For example, a glass sheet including a moisture absorbent layer can be bonded to the cathode to reduce the entry of water or the like into the organic compound layer. Thus, the occurrence of display defects can be reduced. Alternatively, a passivation film composed of silicon nitride or the like may be provided on the cathode to reduce the entry of water or the like into the organic compound layer. The protective layer can be formed by a chemical vapor deposition method (CVD method) or the like. After the film formation by the chemical vapor deposition method, an atomic layer deposition method (ALD method) may be performed to provide a protective layer composed of two layers. For example, after the formation of the cathode, the resulting substrate may be transferred to another chamber while the vacuum is maintained, and a silicon nitride film may be formed thereon as a protective layer by a CVD method. The protective layer preferably has a thickness of 1 μm to 10 μm.

### Color Filter

A color filter can be disposed on a protective layer. For example, a color filter corresponding to the size of the organic light-emitting device may be provided on another substrate and may be bonded to the substrate on which the organic light-emitting device is provided, or a color filter may be patterned by photolithography. The color filter can be formed of a polymeric material or the like.

### Planarization Layer

A planarization layer can be disposed between a color filter and a protective layer. The constituent material of the planarization layer may be an organic compound, and particularly preferably a high-molecular-weight organic compound or the like. The planarization layer may be provided on both sides of a color filter, and, in such a case, the constituent materials of the planarization layers may be the same or different. The constituent material of the planarization layer may be a resin such as a polyvinylcarbazole resin, a polycarbonate resin, a polyester resin, an ABS resin, an acrylic resin, a polyimide resin, a phenolic resin, an epoxy resin, a silicone resin, a urea resin, or the like.

### Opposite Substrate

An opposite substrate can be disposed on a planarization layer. The opposite substrate is disposed to face the substrate and thus is referred to as an opposite substrate. The constituent material of the opposite substrate may be the same as the constituent material of the substrate.

### Organic Compound Layer

Next, an organic compound layer included in an organic light-emitting device according to an embodiment of the present disclosure will be described.

An organic light-emitting device according to the present embodiment at least includes a first electrode and a second electrode, which are a pair of electrodes, and an organic compound layer disposed between the electrodes. In the organic light-emitting device of the present embodiment, the organic compound layer may be a single layer or a laminate of a plurality of layers as long as the organic compound layer includes a light-emitting layer. The pair of electrodes may be an anode and a cathode.

When the organic compound layer is a laminate of a plurality of layers, the organic compound layer may include a light-emitting layer. The organic compound layer may include, besides the light-emitting layer, for example, a hole injection layer, a hole transport layer, an electron-blocking layer, a hole/exciton-blocking layer, an electron transport layer, and an electron injection layer.

The light-emitting layer may be a single layer or a laminate of a plurality of layers. The hole transport layer and the electron transport layer are also referred to as charge transport layers.

In the organic light-emitting device of the present embodiment, at least one layer of the organic compound layer contains a light-emitting composition. Specifically, the light-emitting composition is contained in any of the hole injection layer, the hole transport layer, the electron-blocking layer, the light-emitting layer, the hole/exciton-blocking layer, the electron transport layer, the electron injection layer, and the like and is preferably contained in the light-emitting layer. The transport layers between the first electrode and the light-emitting layer can be collectively referred to as a first charge transport layer. The transport layers between the second electrode and the light-emitting layer can be collectively referred to as a second charge transport layer. That is, the light-emitting layer is in contact with the first charge transport layer and in contact with the second charge transport layer.

In the organic light-emitting device of the present embodiment, when the light-emitting composition is contained in a light-emitting layer, the light-emitting layer may be a layer composed only of an organometallic complex or a layer that contains an organometallic complex and a first organic compound different from the organometallic complex. The organometallic complex preferably has a smaller lowest excited triplet energy than the lowest excited triplet energy of a charge transport material. The first organic compound used in the light-emitting layer together with the organometallic complex may have a lowest excited triplet energy equal to or larger than the lowest excited triplet energy of the organometallic complex. Here, when the light-emitting layer is a layer containing the organometallic complex and the first organic compound, the first organic compound may be a host material of the light-emitting layer. The organometallic complex may be a guest material or a dopant material.

The first organic compound may be an assist material.

Herein, the host material is a compound that is mainly responsible for injection and transport of charges in the light-emitting layer.

In the organic light-emitting device, light emission from the host material itself is not substantially observed in some cases. The host material is preferably a compound having a phosphorescence quantum yield of less than 0.1%, more preferably a compound having a phosphorescence quantum yield of less than 0.01%, at room temperature (25° C.). The guest material or the dopant material is a compound that is responsible for main light emission in the organic light-emitting device. The assist material is a compound that has, among the compounds constituting the light-emitting layer, a lower content than the host and guest materials on a mass basis and that assists the light emission of the guest. The assist material is also referred to as a second host material.

Herein, the doping concentration according to the present embodiment refers to a concentration of the guest relative to the mass of the host in terms of % by mass. The doping concentration is preferably 50% by mass or more and 100% by mass or less.

In addition to the materials described above, the light-emitting composition can optionally contain various additives such as a charge transport material, a resin, a plasticizer, an oxidation inhibitor, and an ultraviolet absorbent. Among these, a resin or a charge transport material (for example, an electron transport material) is preferably contained. The resin is preferably a resin serving as a binder. Specific examples thereof include a polyvinylcarbazole resin, a polycarbonate resin, a polyester resin, an ABS resin, an acrylic resin, a polyimide resin, a phenolic resin, an epoxy resin, a silicone resin, and a urea resin.

The resin may be a homopolymer or a copolymer, and one or two or more resins can be used. The electron transport material may be a publicly known material. For example, 1,3-bis[2-(4-tert-butylphenyl)-1,3,4-oxadiazo-5-yl]benzene or the like may be used. The electron transport material may be a commercially available product (for example, trade name “OXD-7”, manufactured by Luminescence Technology Corp.) or the like.

The light-emitting composition may be a liquid. To provide a liquid light-emitting composition, an organic solvent is contained. The organic solvent may be any organic solvent that can dissolve or disperse the compound according to the present disclosure. In particular, an organic solvent having a boiling point of 70° C. or higher and 300° C. or lower at 1 atm is preferably used. The content (% by mass) of the organic solvent in a liquid light-emitting composition is preferably 85% by mass or more and 99% by mass or less, based on the total mass of the light-emitting composition.

Specific examples of the organic solvent include toluene, o-xylene, p-xylene, mesitylene, chlorobenzene, dichlorobenzene, diethyl ether, dibutyl ether, tetrahydrofuran, 2-methyltetrahydrofuran, 1,4-dioxane, anisole, 4-methylanisole, phenylcyclohexane, dimethoxyethane, diethylene glycol dimethyl ether, ethyl acetate, butyl acetate, methyl benzoate, cyclopentanone, cyclohexanone, dimethylformamide, dimethylacetamide, methyl ethyl ketone, N-methylpyrrolidone, and dimethylimidazolidinone. The organic solvents may be used alone or in combination of two or more thereof in order to adjust the compatibility of various materials in the light-emitting composition and various characteristics such as the viscosity and surface tension of the liquid.

The lowest excited triplet energy of the first charge transport layer is preferably larger than the lowest excited triplet energy of the first organic compound. The lowest excited triplet energy of the second charge transport layer is preferably larger than the lowest excited triplet energy of the first organic compound. The lowest excited triplet energy of each charge transport layer can be estimated by the lowest excited triplet energy of the constituent material of the layer. When the charge transport layer is composed of a plurality of materials, the lowest excited triplet energy may be the lowest excited triplet energy of a compound having a high weight proportion.

The inventors have conducted various studies and found that use of the organometallic complex according to the present embodiment as a guest of a light-emitting layer achieves high efficiency. This light-emitting layer may be composed of a single layer or multiple layers, and can also contain a light-emitting material having another emission color to thereby form a color mixture of the emission color of the present embodiment and the other emission color.

The term “multiple layers” means a state in which a plurality of light-emitting layers are stacked. In this case, the emission color of the organic light-emitting device is not limited to the same hue as the emission color of the single layer. More specifically, the emission color may be white or an intermediate color. In the case of white, red light, blue light, and green light may be emitted from the light-emitting layers to obtain white light, or complementary emission colors may be combined to obtain white light.

The organometallic complex according to the present embodiment can be used as a constituent material of an organic compound layer other than the light-emitting layer constituting the organic light-emitting device of the present embodiment. Specifically, the organometallic complex may be used as a constituent material of the electron transport layer, the electron injection layer, the hole transport layer, the hole injection layer, the hole-blocking layer, or the like. In the case where the light-emitting layer is composed of a plurality of light-emitting layers, a charge generation layer may be disposed between the light-emitting layers. The charge generation layer may be composed of a compound having LUMO energy lower than the hole transport layer. That is, the LUMO energy of the charge generation layer may be lower than the HOMO energy of the hole transport layer. Here, the molecular orbital energy of the organic compound layer may be the molecular orbital energy of the organic compound having the largest proportion by weight in the organic compound layer.

Here, the HOMO energy level and the LUMO energy level are described as “higher” as they are closer to the vacuum level. The expression “the LUMO energy of the charge generation layer is lower than the HOMO energy of the hole transport layer” indicates that the LUMO energy of the charge generation layer is farther from the vacuum level than the HOMO energy of the hole transport layer.

HOMO and LUMO in this specification can be calculated by molecular orbital calculation. The molecular orbital calculation is performed according to the density functional theory (DFT) or the like using B3LYP as the functional and 6-31G* as the basis function, for example. The molecular orbital calculation can be performed by using, for example, Gaussian 09 (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010.).

HOMO and LUMO in this specification can be calculated using ionization potentials and band gaps. HOMO can be estimated by measuring the ionization potential. The ionization potential can be measured by dissolving a target compound in a solvent, such as toluene, or depositing a target compound by vapor deposition on a substrate, such as a glass substrate, and performing measurement with a measurement apparatus, such as AC-3. The band gap can be measured by dissolving a target compound in a solvent, such as toluene, and irradiating the resulting solution with excitation light. The band gap can be measured by measuring the absorption edge of the absorption spectrum of the excitation light. Alternatively, the measurement can be performed by depositing a target compound using vapor deposition on a substrate, such as a glass substrate, and irradiating the vapor-deposited film with excitation light. The band gap can be measured by measuring the absorption edge of the absorption spectrum of the vapor-deposited film when the film absorbs the excitation light.

LUMO can be calculated using the values of the band gap and the ionization potential. LUMO can be estimated by subtracting the value of the ionization potential from the value of the band gap.

LUMO can also be estimated from a reduction potential. For example, a one-electron reduction potential is estimated by cyclic voltammetry (CV) measurement. The CV measurement can be performed, for example, in a DMF solution of 0.1 M tetrabutylammonium perchlorate using Ag/Ag⁺ as a reference electrode, Pt as a counter electrode, and glassy carbon as a working electrode. LUMO can be estimated by adding the difference between the obtained reduction potential of the compound and the reduction potential of ferrocene to −4.8 eV.

In manufacturing the organic light-emitting device according to the present embodiment, publicly known low-molecular-weight and high-molecular-weight hole injection compounds or hole transport compounds, compounds serving as the host, light-emitting compounds, and electron injection compounds or electron transport compounds, etc. can be used in combination as necessary. Examples of these compounds will be described below.

The hole injection/transport material is preferably a material having a high hole mobility so as to facilitate hole injection from the anode and to enable the injected holes to be transported to the light-emitting layer. The hole injection/transport material is preferably a material having a high glass transition temperature in order to reduce degradation of the film quality, such as crystallization, in the organic light-emitting device. Examples of the low-molecular-weight and high-molecular-weight materials having such hole injection/transport performance include triarylamine derivatives, arylcarbazole derivatives, phenylenediamine derivatives, triazole derivatives, oxadiazole derivatives, imidazole derivatives, stilbene derivatives, phthalocyanine derivatives, porphyrin derivatives, polyarylamine derivatives, polyvinylcarbazole derivatives, polythiophene derivatives, and other conductive polymers such as PEDOT-PSS, copolymers thereof, and mixtures thereof. Furthermore, the above hole injection/transport materials are also suitable for use in an electron-blocking layer.

Specific examples of the compound used as the hole injection/transport material are shown below, but of course, the hole injection/transport material is not limited thereto.

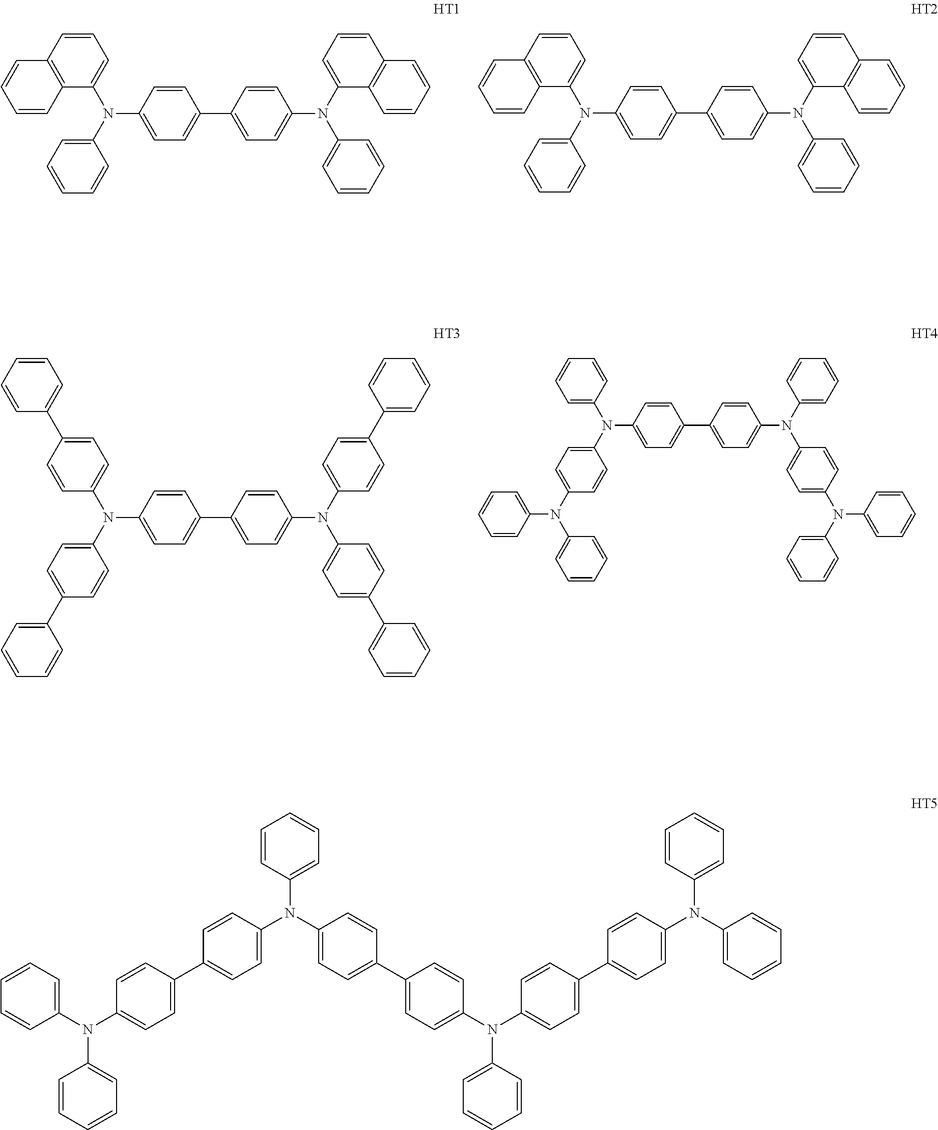 [SMILES: c1ccc(N(c2ccc(-c3ccc(N(c4ccccc4)c4cccc5ccccc45)cc3)cc2)c2cccc3ccccc23)cc1 ; c1ccc(N(c2ccc(-c3ccc(N(c4ccccc4)c4cccc5ccccc45)cc3)cc2)c2cccc3ccccc23)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccccc2)c2ccc(N(c3ccccc3)c3ccc(-c4ccc(N(c5ccccc5)c5ccc(N(c6ccccc6)c6ccccc6)cc5)cc4)cc3)cc2)cc1 ; c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1]

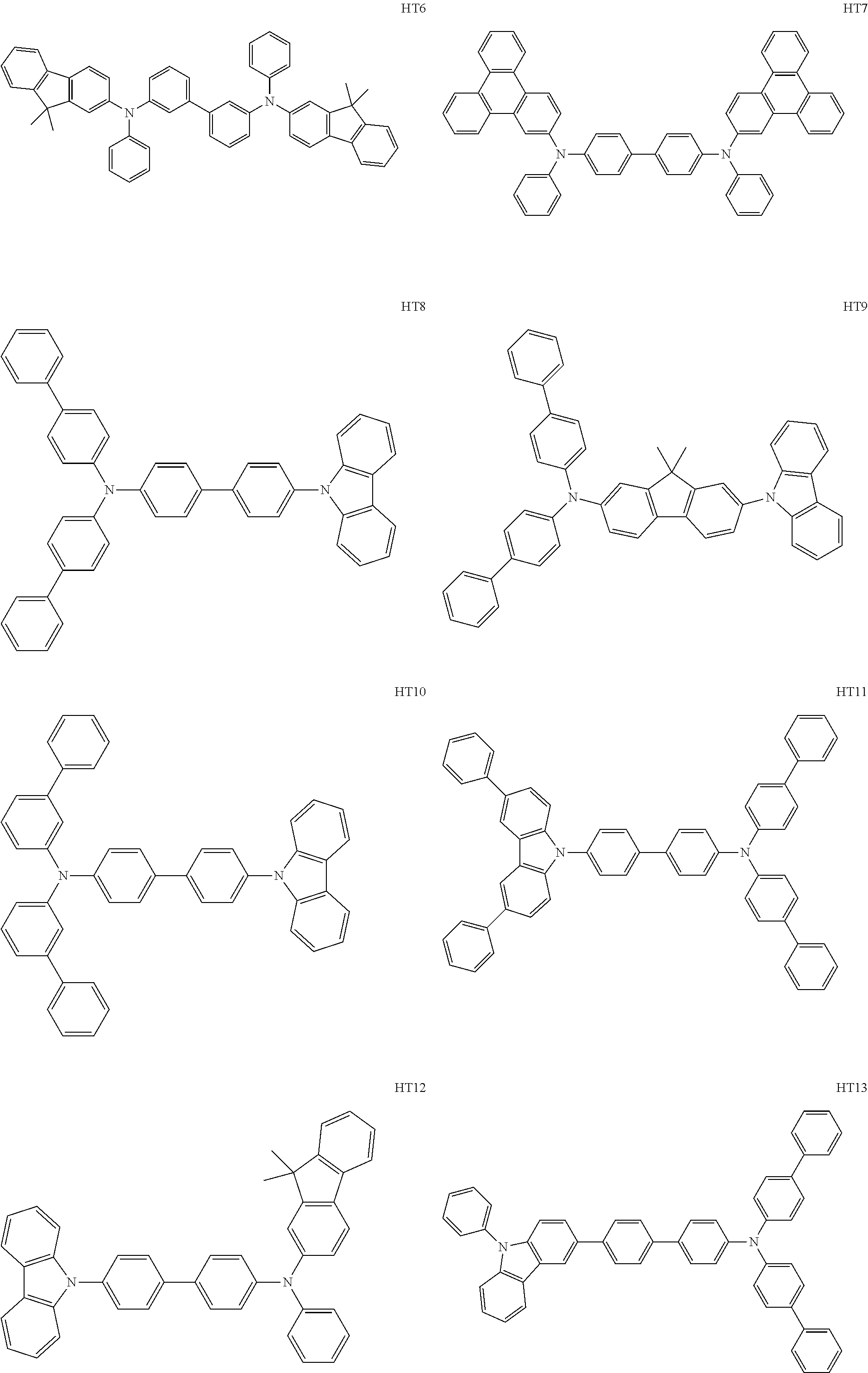

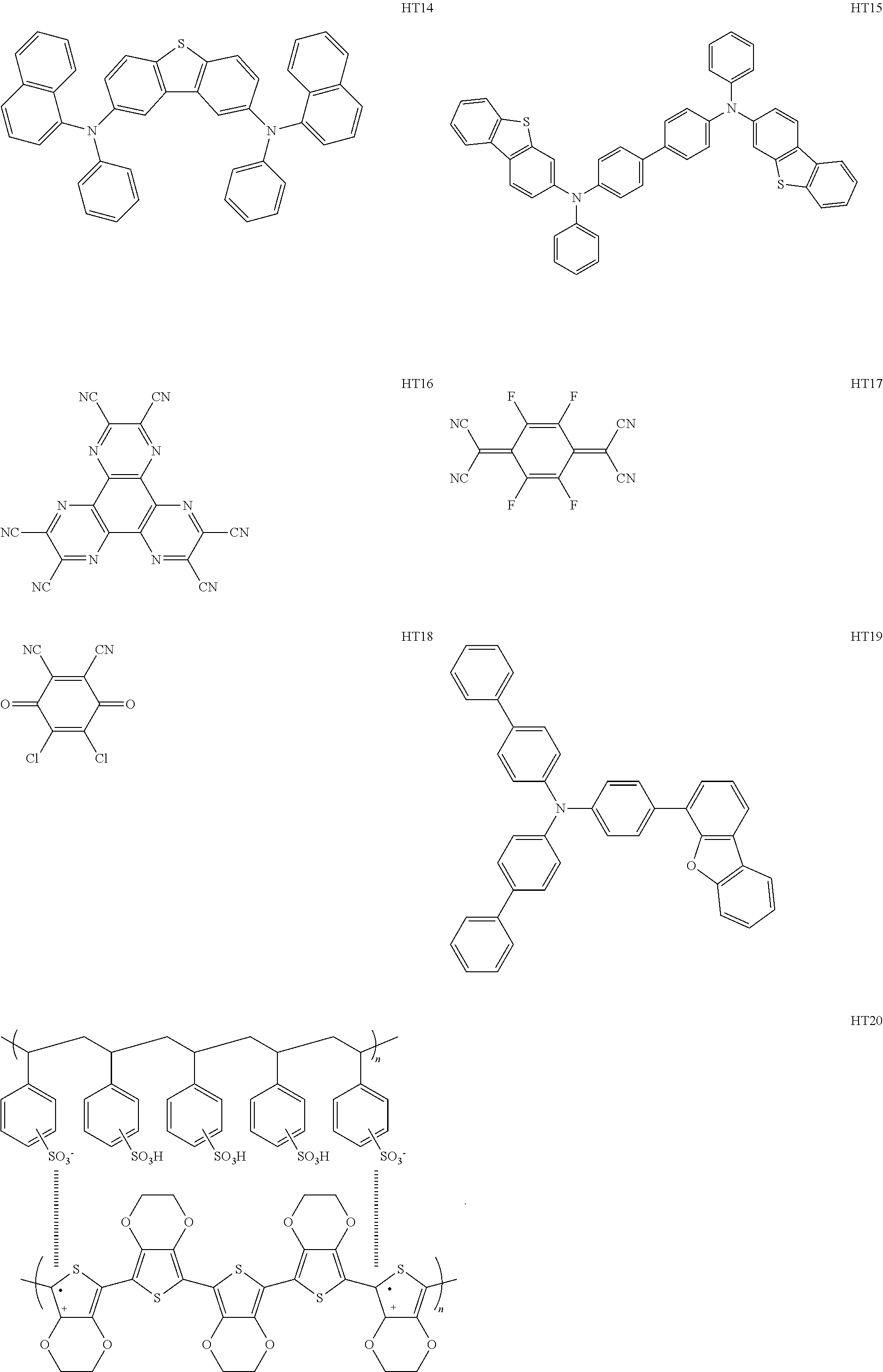

As the light-emitting material that is mainly associated with a light-emitting function, another light-emitting material can be added in addition to the organometallic complex according to an embodiment of the present disclosure. Examples of the other light-emitting material include fused-ring compounds (such as fluorene derivatives, naphthalene derivatives, pyrene derivatives, perylene derivatives, tetracene derivatives, anthracene derivatives, and rubrene), quinacridone derivatives, coumarin derivatives, stilbene derivatives, organoaluminum complexes such as tris(8-quinolinolato)aluminum, iridium complexes such as tris(2-phenylpyridinato) iridium, platinum complexes, rhenium complexes, copper complexes, europium complexes, ruthenium complexes, and polymer derivatives such as poly(phenylene vinylene) derivatives, poly(fluorene) derivatives, and poly(phenylene) derivatives. Specific examples of the compound used as the light-emitting material are shown below, but of course, the light-emitting material is not limited thereto.

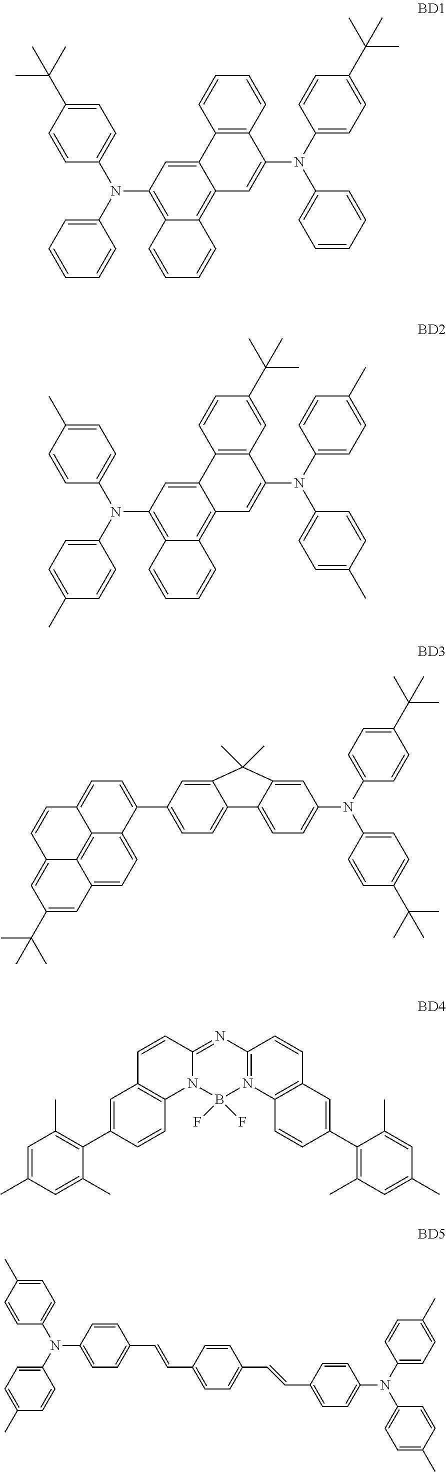

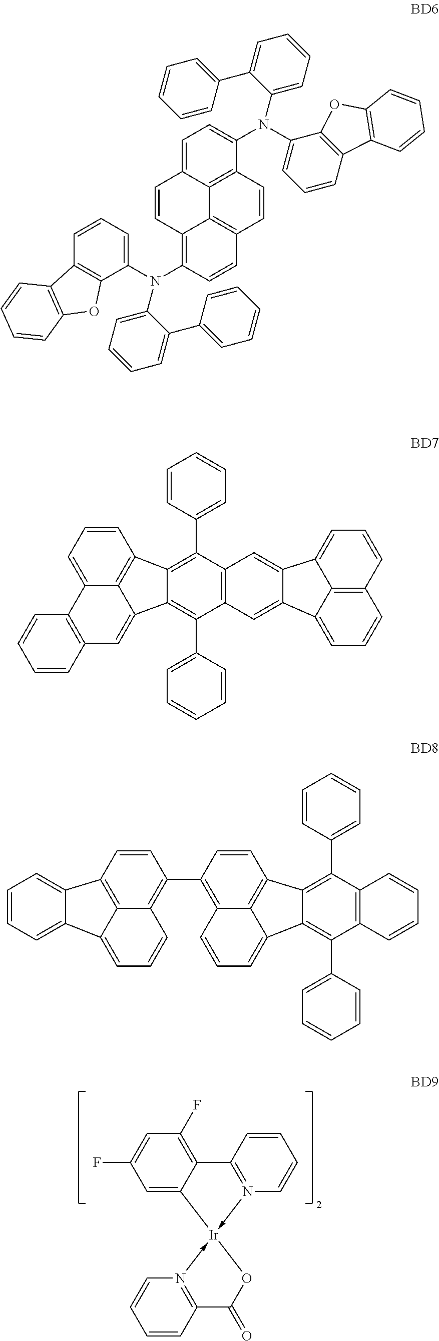

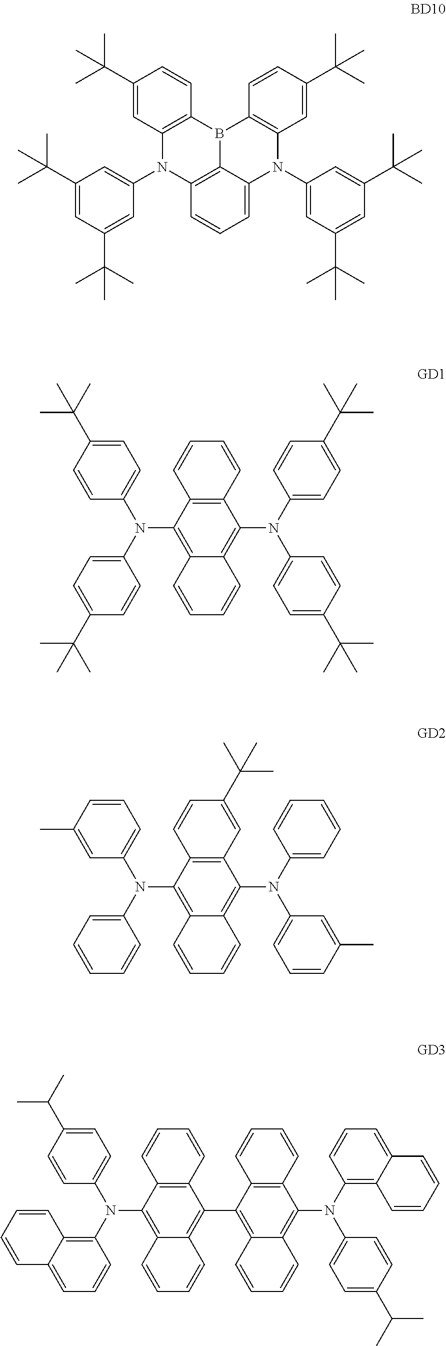

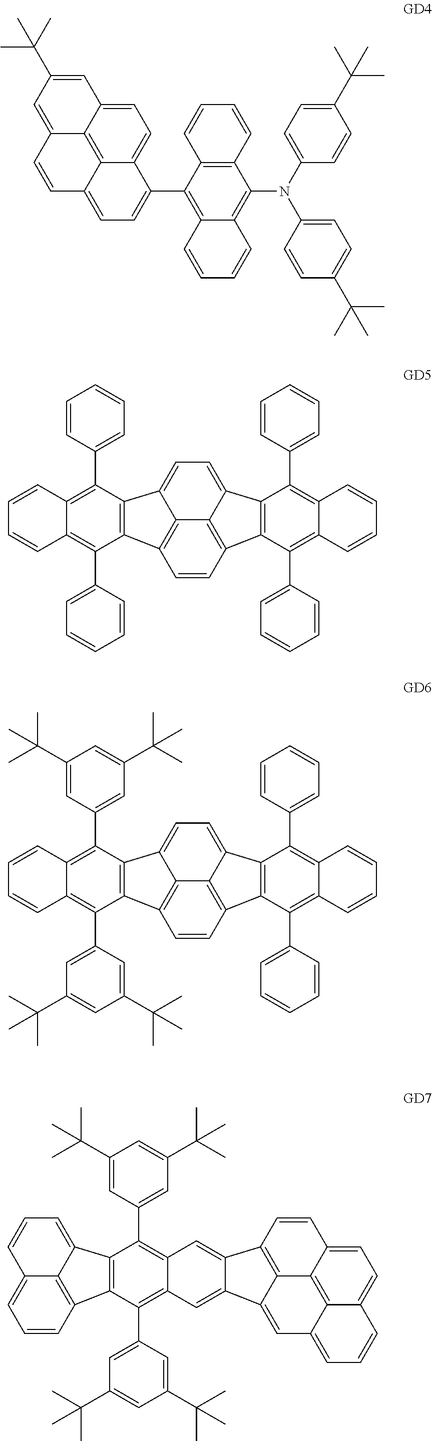

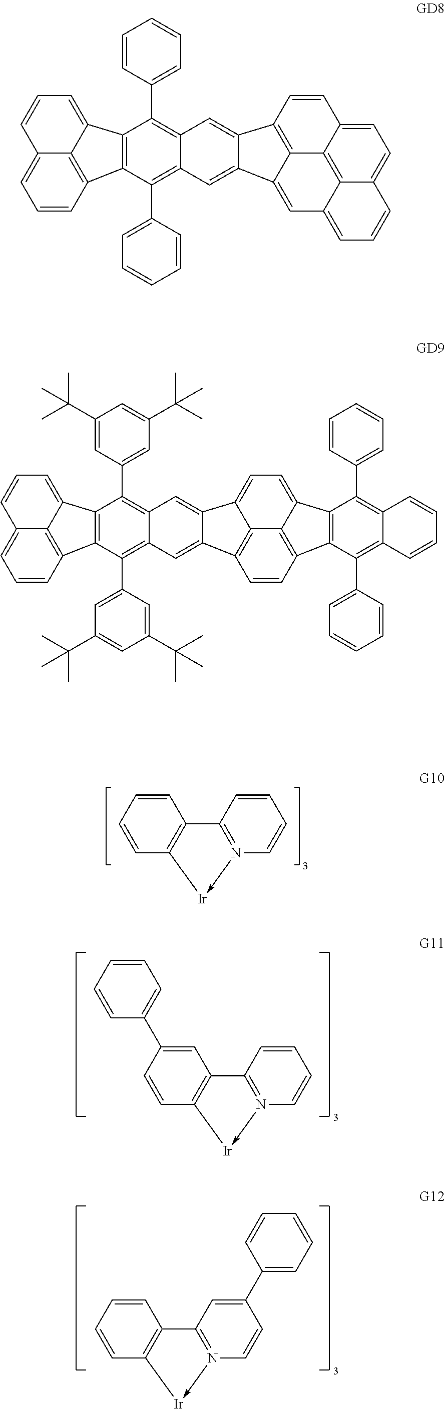

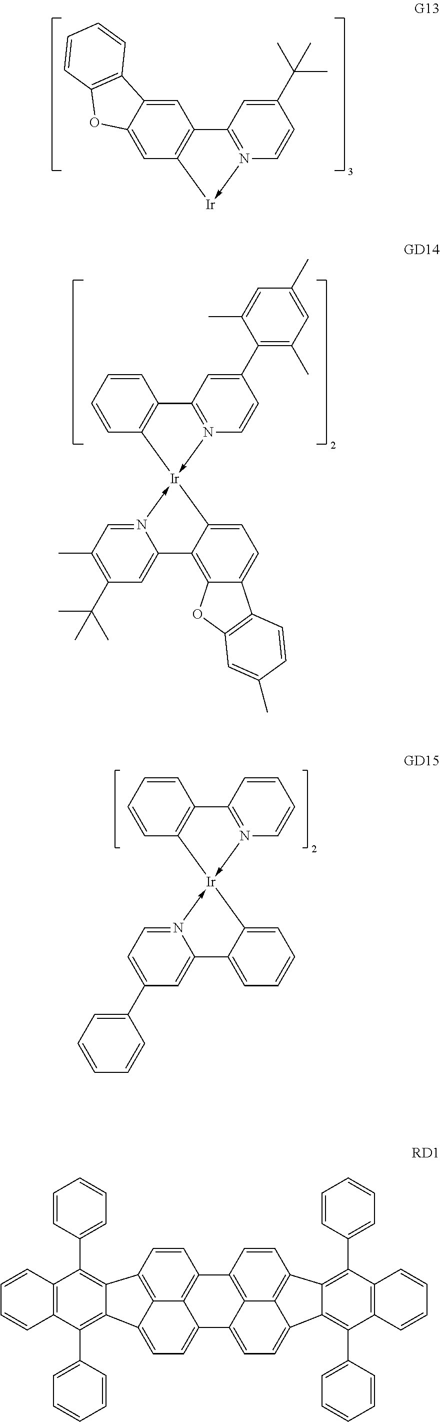

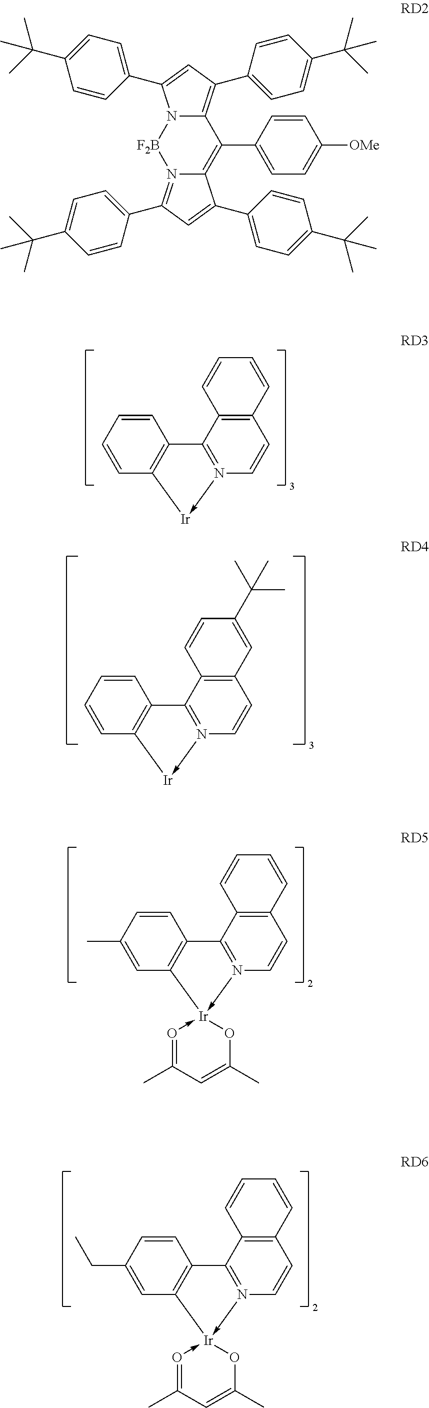

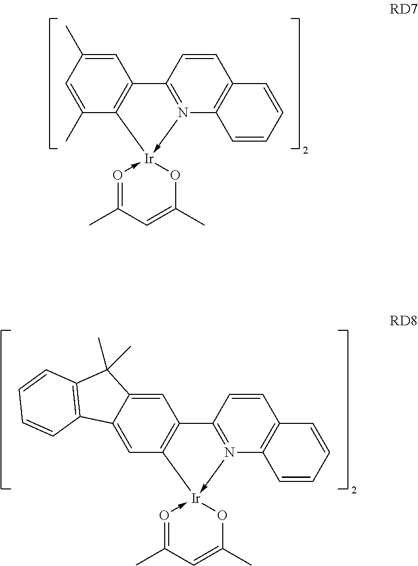

Examples of the assist material contained in the light-emitting layer include, in addition to aromatic hydrocarbon compounds and derivatives thereof, carbazole derivatives, dibenzofuran derivatives, dibenzothiophene derivatives, triazine derivatives, organoaluminum complexes such as tris(8-quinolinolato)aluminum, organoberyllium complexes, polymers such as polyphenylene derivatives, polyphenylene vinylene derivatives, polyfluorene derivatives, and polyvinyl carbazole derivatives, copolymers thereof, and mixtures thereof.

Specific examples of the compound used as the assist material contained in the light-emitting layer are shown below, but of course, the assist material is not limited thereto.

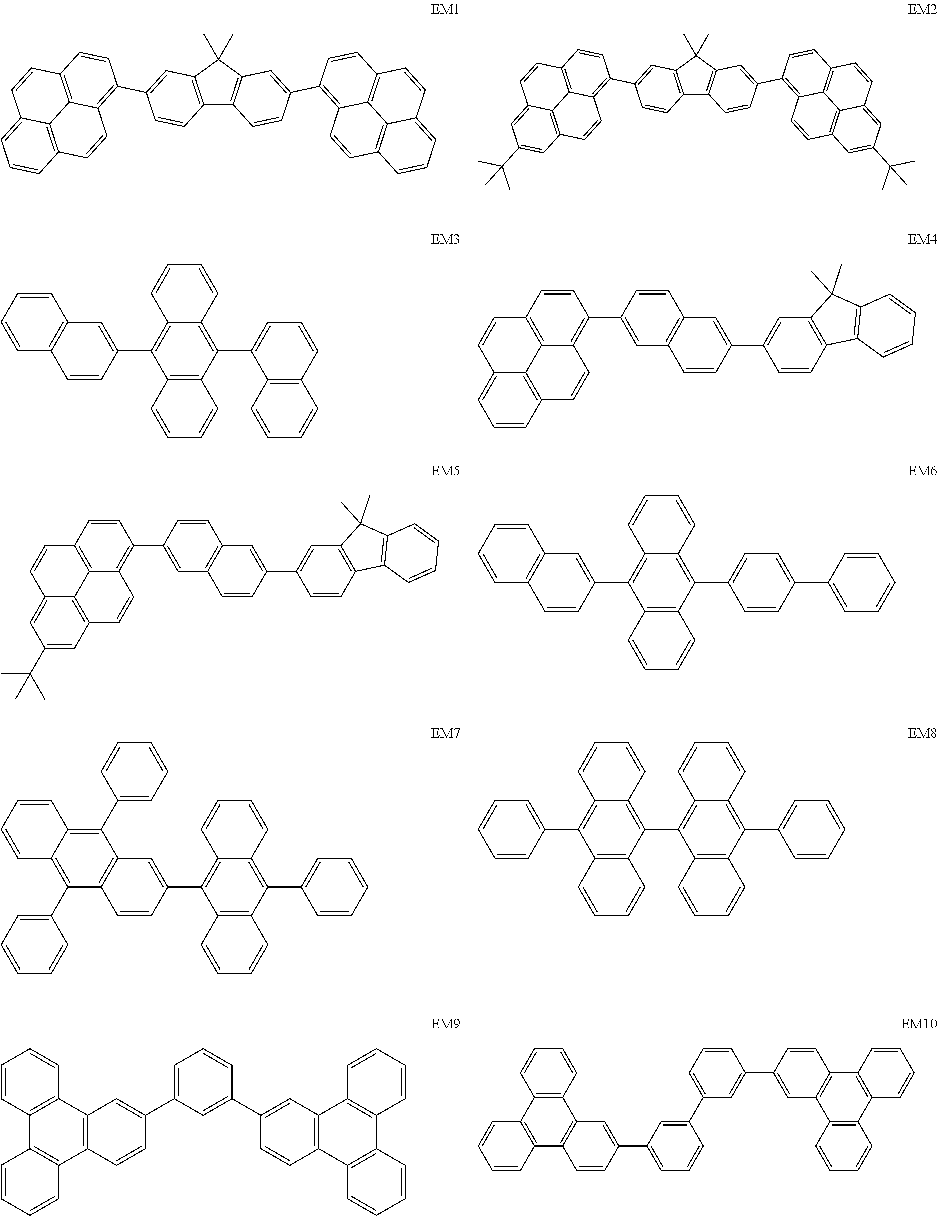

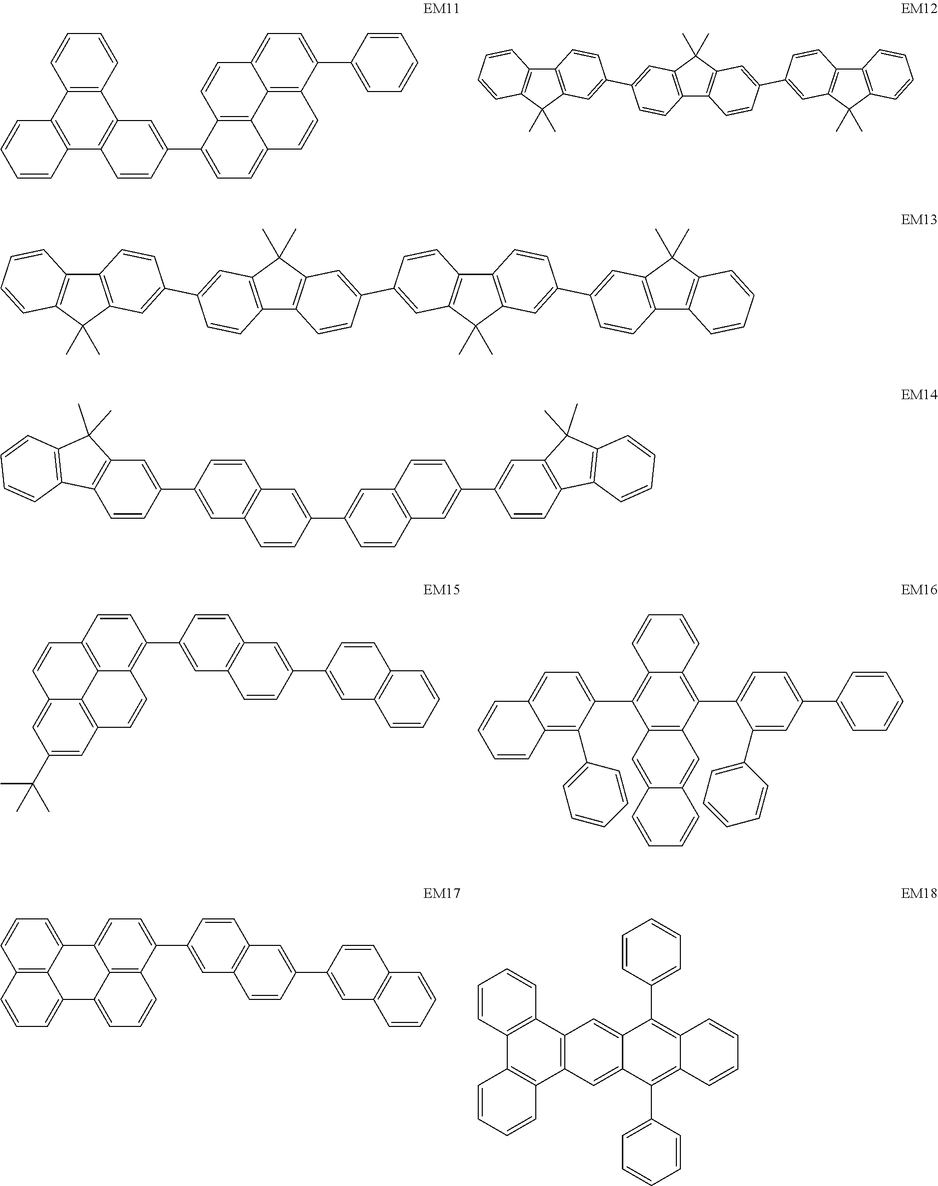

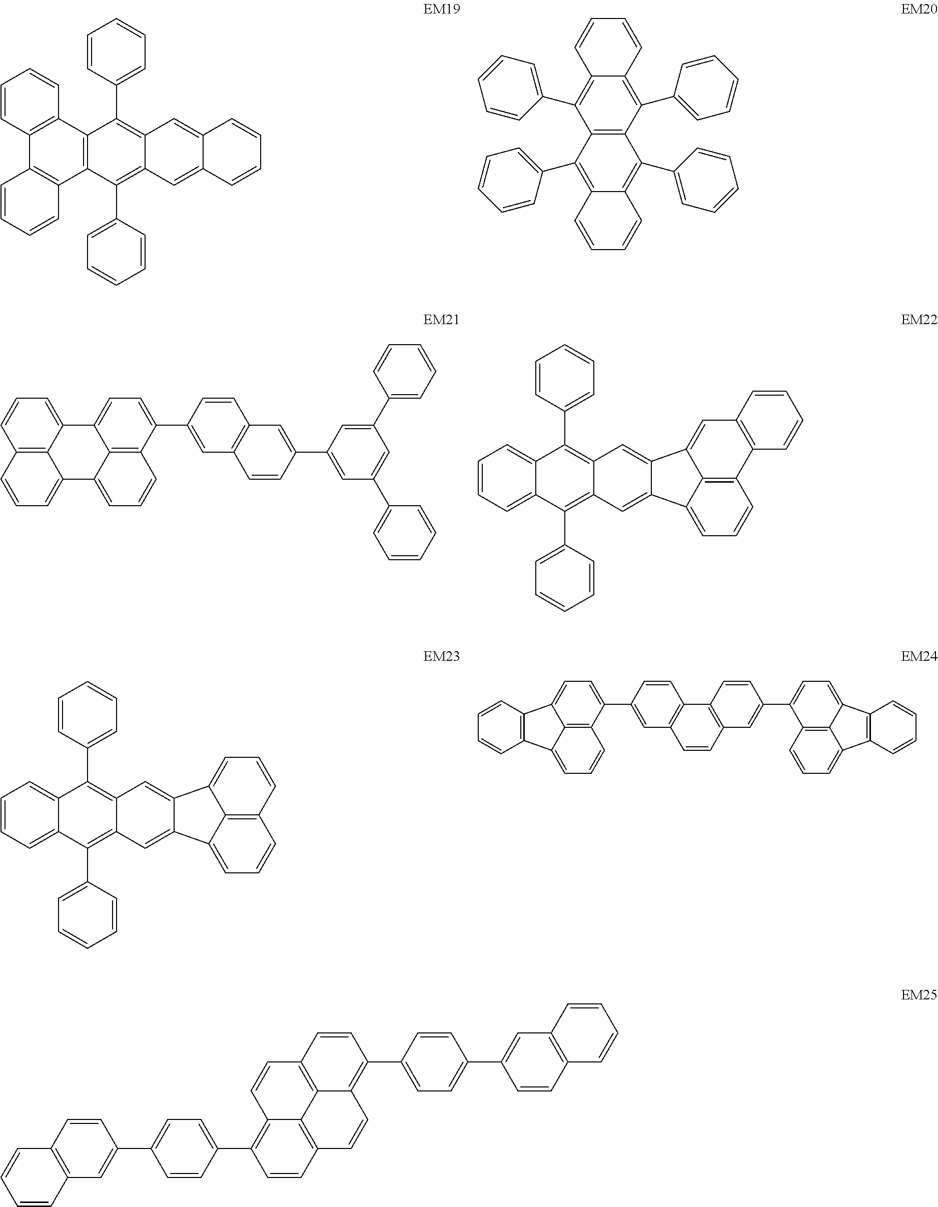

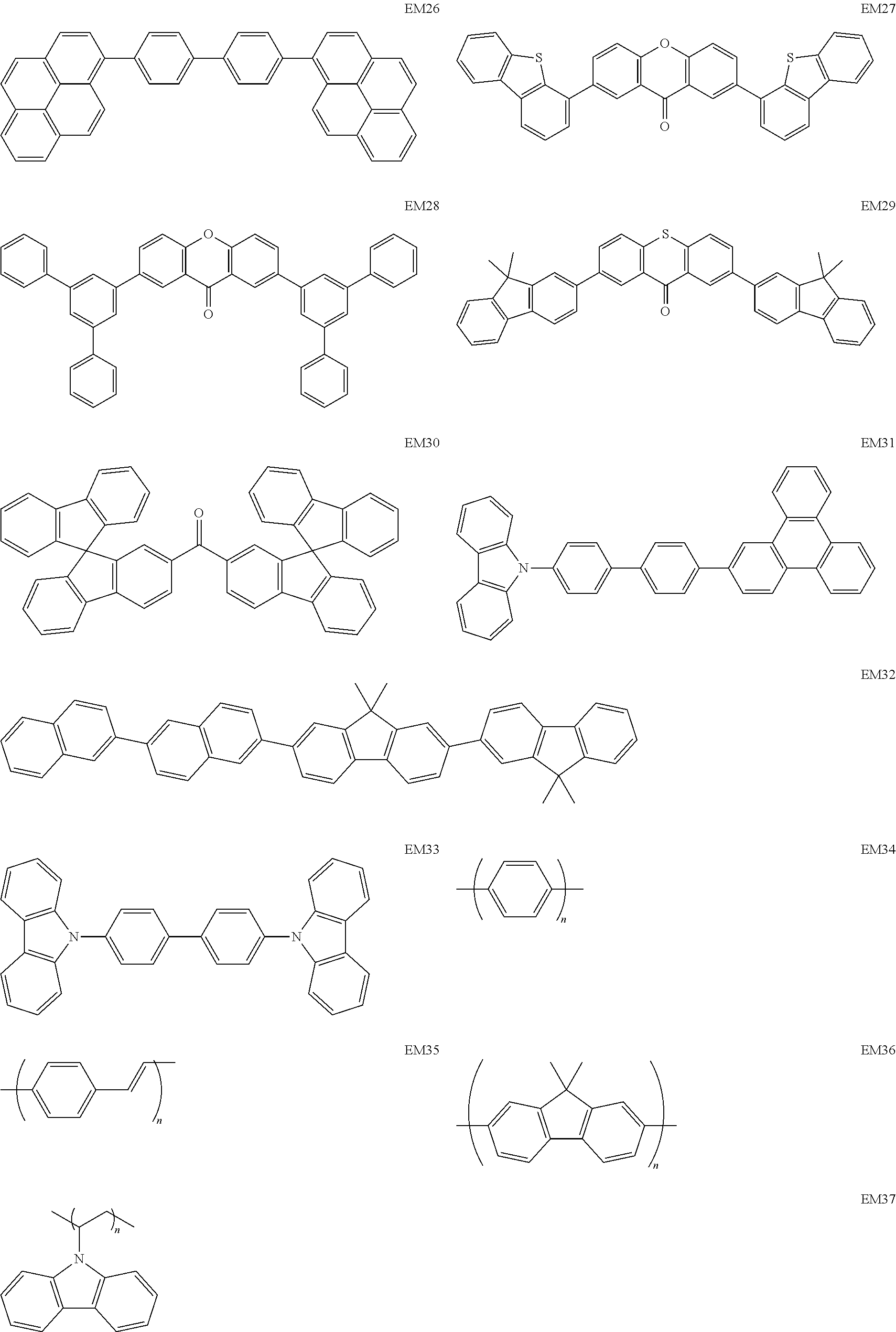

The electron transport material can be freely selected from materials capable of transporting electrons injected from the cathode to the light-emitting layer and is selected in consideration of, for example, the balance with the hole mobility of the hole transport material. Examples of the material having such electron transport performance include oxadiazole derivatives, oxazole derivatives, pyrazine derivatives, triazole derivatives, triazine derivatives, quinoline derivatives, quinoxaline derivatives, phenanthroline derivatives, organoaluminum complexes, and fused-ring compounds (such as fluorene derivatives, naphthalene derivatives, chrysene derivatives, and anthracene derivatives). The above electron transport materials are also suitable for use in a hole-blocking layer.

Specific examples of the compound used as the electron transport material are shown below, but of course, the electron transport material is not limited thereto.

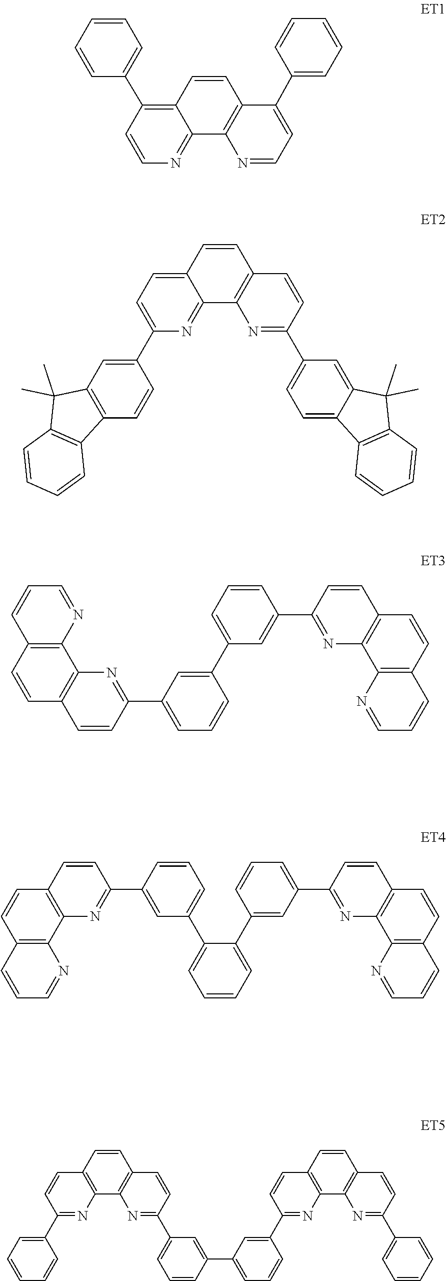

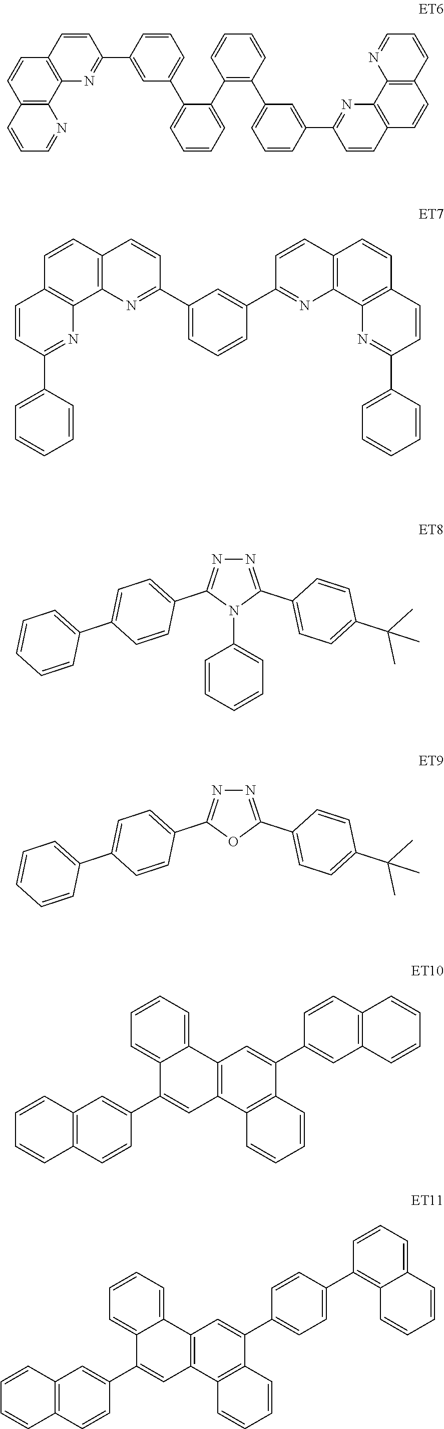

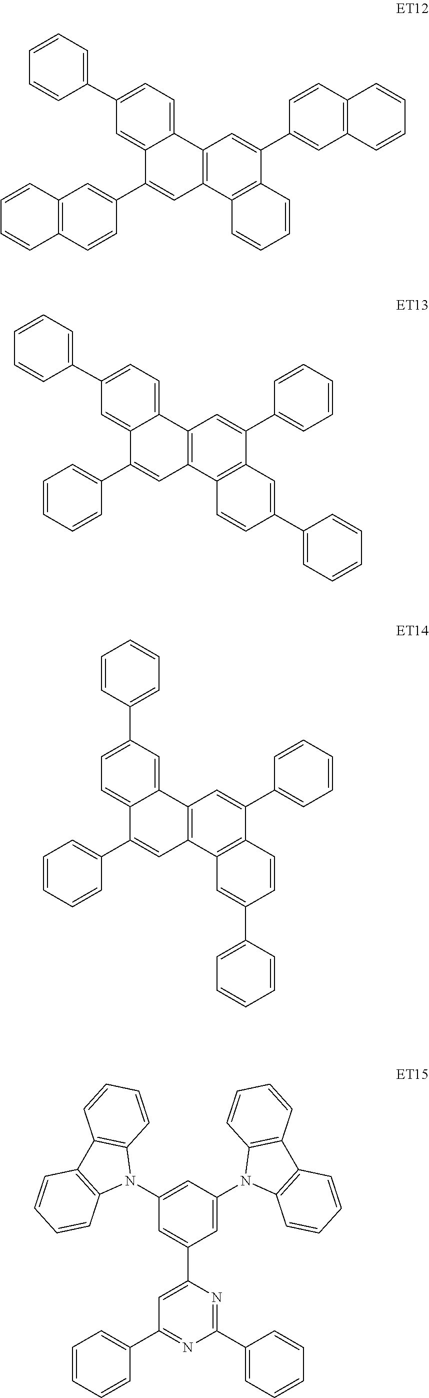

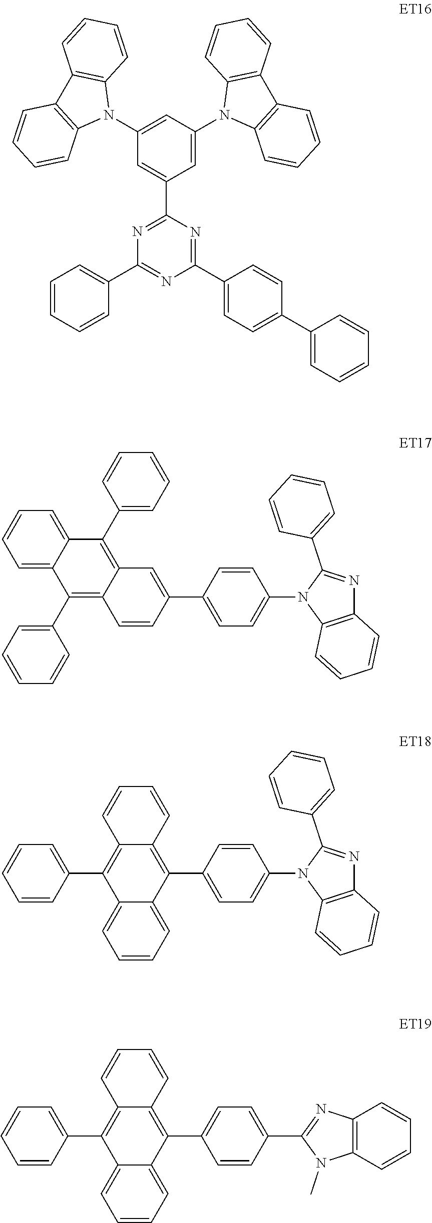 [SMILES: c1ccc(-c2ccc(-c3nc(-c4ccccc4)nc(-c4cc(-n5c6ccccc6c6ccccc65)cc(-n5c6ccccc6c6ccccc65)c4)n3)cc2)cc1 ; c1ccc(-c2c3ccccc3c(-c3ccccc3)c3cc(-c4ccc(-n5c(-c6ccccc6)nc6ccccc65)cc4)ccc23)cc1 ; c1ccc(-c2c3ccccc3c(-c3ccc(-n4c(-c5ccccc5)nc5ccccc54)cc3)c3ccccc23)cc1 ; Cn1c(-c2ccc(-c3c4ccccc4c(-c4ccccc4)c4ccccc34)cc2)nc2ccccc21]

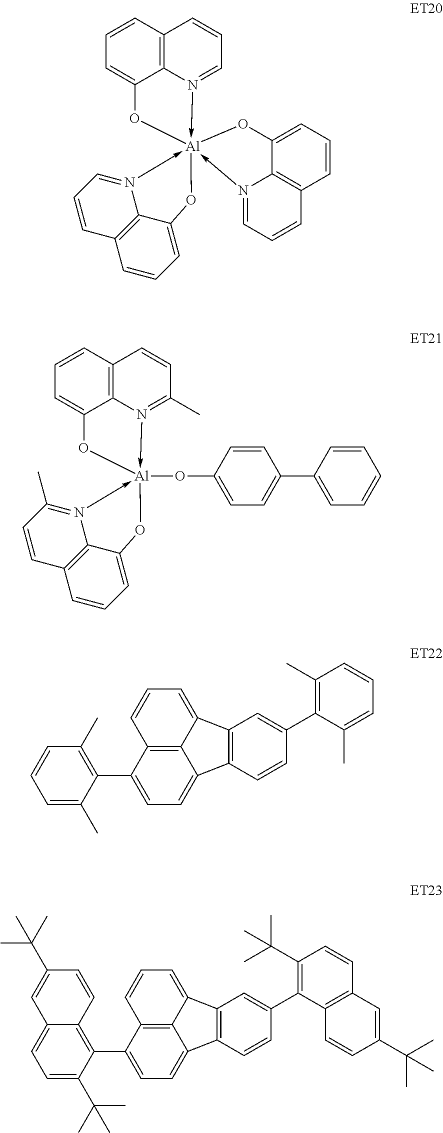

The electron injection material can be freely selected from materials capable of easily injecting electrons from the cathode and is selected in consideration of, for example, the balance with the hole injection property. As an organic compound, n-type dopants and reducing dopants are also included. Examples thereof include alkali metal-containing compounds such as lithium fluoride, lithium complexes such as lithium quinolinol, benzimidazolidene derivatives, imidazolidene derivatives, fulvalene derivatives, and acridine derivatives.

### Method for Manufacturing Organic Light-Emitting Device

A method for manufacturing an organic light-emitting device including an organic compound layer (such as a hole injection layer, a hole transport layer, an electron-blocking layer, a light-emitting layer, a hole-blocking layer, an electron transport layer, or an electron injection layer) is described below. The organic light-emitting device is manufactured by a manufacturing method including a step of applying a light-emitting composition to a base material to form an organic compound layer.

The method for forming the organic compound layer is, for example, a dry process or a wet process. Examples of the dry process include a vacuum deposition method, an ionized deposition method, a sputtering method, and a plasma method. Examples of the wet process include publicly known methods such as coating methods, e.g., a spin coating method, a casting method, a gravure coating method, a bar coating method, a roll coating method, a wire bar coating method, a dip coating method, a spray coating method, and a capillary coating method; and printing methods, e.g., a screen printing method, a flexographic printing method, an offset printing method, and an ink jet method.

Among these, a vacuum deposition method, an ionized deposition method, a spray coating method, or an ink jet method is preferably used as the method for forming the organic compound layer from the viewpoint that film uniformity and formation of large-area pixels can be combined in the formation of a thin film with a film thickness of several nanometers. Furthermore, from the viewpoints of material utilization efficiency and the manufacturing cost, a spray coating method or an ink jet method is preferably used.

After the organic compound layer is formed by the wet process, the organic solvent is preferably dried. The drying conditions can be appropriately determined according to the constituent materials of the organic compound layer and the like.

The drying is preferably performed in an atmosphere of air or inert gas (such as nitrogen or argon). The heating temperature for drying is preferably 100° C. or higher and 250° C. or lower, more preferably 110° C. or higher and 200° C. or lower. The heating time for drying is preferably 5 minutes or more and 60 minutes or less. The pressure during heating for drying may be atmospheric pressure (1 atm) or reduced pressure (100 Pa to 0.1 MPa). Various conditions (temperature, pressure, and time) in the drying step are determined so that the organic solvent can be removed from the organic compound layer and the like.

When the organic compound layer is formed by the wet process using a liquid light-emitting composition, it is preferable to appropriately determine the composition. The mass ratio of the amount (% by mass) of organic solvent used as the organic solvent in the light-emitting composition to the total amount (% by mass) of solid components constituting the organic compound layer is preferably 10.0 times or more and 100.0 times or less. The solid components constituting the organic compound layer are, for example, an organometallic complex and a charge transport material.

When an organic compound layer is formed by applying a liquid light-emitting composition to a base material by an ink jet method, it is preferable to appropriately control the physical properties of the light-emitting composition. The liquid light-emitting composition preferably has a surface tension of 15 mN/m or more and 75 mN/m or less, more preferably 25 mN/m or more and 45 mN/m or less, at 25° C. The surface tension of the liquid light-emitting composition can be adjusted by appropriately determining the type and content of organic solvent in the light-emitting composition. The liquid light-emitting composition preferably has a viscosity of 0.1 mPa's or more and 20.0 mPa's or less, more preferably 0.5 mPa's or more and 10.0 mPa's or less, at 25° C. By adjusting the viscosity to the above range, clogging or ejection failure in a liquid ejection head can be suppressed during ejection by an ink jet method.

### Pixel Circuit

An organic light-emitting apparatus may include a pixel circuit connected to an organic light-emitting device. The pixel circuit is preferably an active matrix-type circuit that independently controls light emission of a plurality of organic light-emitting devices. The active matrix-type circuit may be a voltage programming or current programming circuit. A driving circuit has a pixel circuit for each pixel. The pixel circuit may have a transistor that controls the emission luminance of the organic light-emitting device, a transistor that controls the timing of light emission, a capacitor that holds the gate voltage of the transistor that controls the emission luminance, and a transistor for establishing the connection to a ground without the organic light-emitting device.

The light-emitting apparatus has a display region and a peripheral region disposed around the display region. The display region includes a pixel circuit, and the peripheral region includes a display control circuit. The mobility of a transistor constituting the pixel circuit may be smaller than the mobility of a transistor constituting the display control circuit. The slope of the current-voltage characteristics of a transistor constituting the pixel circuit may be smaller than the slope of the current-voltage characteristics of a transistor constituting the display control circuit. The slope of the current-voltage characteristics can be measured by the so-called Vg-Ig characteristics. A transistor constituting the pixel circuit is a transistor connected to an organic light-emitting device.

### Pixel

The organic light-emitting apparatus includes a plurality of pixels. Each of the plurality of pixels includes subpixels that emit light of a color different from the other colors. The subpixels each independently emit light of colors of RGB. The pixels each emit light in a region that is also called a pixel aperture. The pixel aperture preferably has a size of 15 μm or less and 5 μm or more. The pixel aperture may be, for example, 11.0 μm, 9.5 μm, 7.4 μm, or 6.4 μm. The distance between the subpixels is preferably 10 μm or less. The distance between the subpixels may be, for example, 8.0 μm, 7.4 μm, or 6.4 μm.

The arrangement of the pixels in plan view can be a publicly known arrangement form. Specific examples of the arrangement form include the stripe arrangement, the delta arrangement, the PenTile arrangement, and the Bayer arrangement. The subpixels may have any publicly known planar shape. Specifically, the shape may be a quadrangle such as a rectangle or a rhombus, or a hexagon. Here, regarding the planar shapes of the subpixels, figures that are not exactly rectangles but are close to rectangles are also regarded as rectangles. The planar shape of the subpixels and the pixel array can be used in combination.

### Applications of Organic Light-Emitting Device

An organic light-emitting device can be used as a constituent member of a display apparatus or an illumination apparatus. Other applications include, for example, an exposure light source of an electrophotographic image recording apparatus, a backlight of a liquid crystal display apparatus, and a light-emitting apparatus including a color filter on a white light source.

The display apparatus includes an image input unit to which image information is input from an area CCD, a linear CCD, a memory card, or the like and an information processing unit configured to process the input information. The display apparatus may be an image information processing apparatus that displays an input image on a display unit. The display unit of an imaging apparatus or an ink jet recording apparatus may have a touch panel function. Specific examples of a method for driving the touch panel function include an infrared radiation method, an electrostatic capacitance method, a resistive film method, and an electromagnetic induction method. The display apparatus may be used for a display unit of a so-called composite recording apparatus.

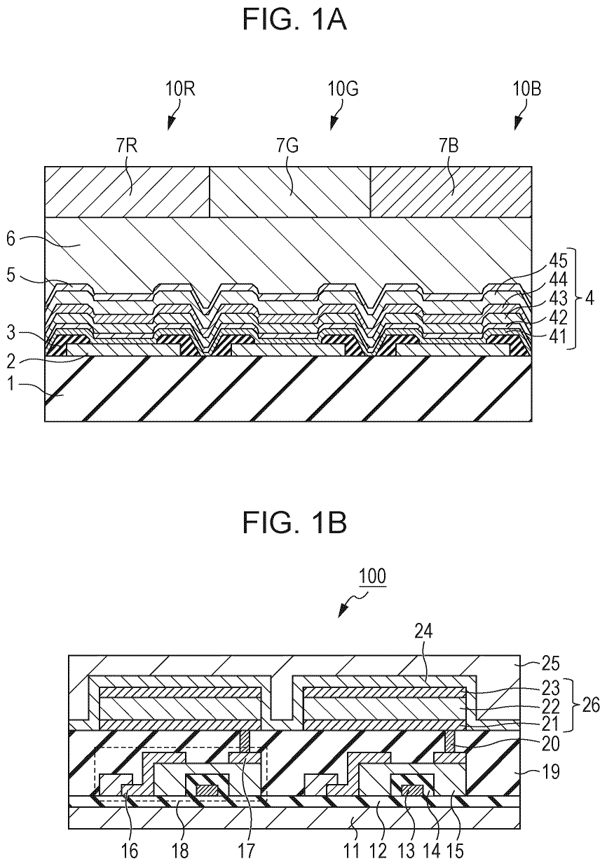

Next, a display apparatus will be described with reference to the drawings. FIG. 1A is a schematic sectional view illustrating an example of a pixel constituting a display apparatus. The pixel has subpixels 10. The subpixels 10 are separated into 10R, 10G, and 10B according to their light emission. The emission color may be distinguished and determined on the basis of the wavelength of light emitted from the light-emitting layer or may be determined by selective transmission or color conversion of light emitted from the subpixels 10 through a color filter or the like. Each of the subpixels 10 includes, on an interlayer insulating layer 1, a reflective electrode 2 which is a first electrode, an insulating layer 3 covering ends of the reflective electrode 2, an organic compound layer 4 covering the first electrode and the insulating layer, a transparent electrode 5, a protective layer 6, and a color filter 7.

In the illustrated direction, the interlayer insulating layer 1 may have transistors and capacitor elements arranged in a layer disposed thereunder or an interior thereof. Each transistor and the first electrode may be electrically connected to each other through a contact hole or the like not illustrated in the drawing. The insulating layer 3 is also referred to as a bank or a pixel isolation film. The insulating layer 3 covers ends of the first electrode and is disposed so as to surround the first electrode. The portion where the insulating layer 3 is not disposed is in contact with the organic compound layer 4 and serves as a light-emitting region. The organic compound layer 4 includes a hole injection layer 41, a hole transport layer 42, a first light-emitting layer 43, a second light-emitting layer 44, and an electron transport layer 45. The second electrode 5 may be a transparent electrode, a reflective electrode, or a semi-transparent electrode. The protective layer 6 reduces the penetration of a liquid component such as water into the organic compound layer. Although the protective layer is illustrated as a single layer in the drawing, the protective layer may be composed of a plurality of layers. In the case of being composed of a plurality of layers, an inorganic compound layer or an organic compound layer may be included. The color filter 7 is separated into 7R, 7G, and 7B according to the colors thereof. The color filter may be formed on a planarization film not illustrated in the drawing. Furthermore, a resin protective layer not illustrated in the drawing may be disposed on the color filter. The color filter may be formed on the protective layer 6 or may be provided on and then bonded to an opposite substrate such as a glass substrate.

FIG. 1B is a schematic sectional view illustrating an example of a display apparatus including organic light-emitting devices and transistors connected to the organic light-emitting devices. The transistors are each an example of an active element.

The transistors may be thin-film transistors (TFTs). A display apparatus 100 illustrated in FIG. 1B includes a substrate 11 formed of glass, silicon, or the like and an insulating layer 12 provided on the substrate 11. On the insulating layer 12, active elements 18 such as TFTs are disposed, and a gate electrode 13, a gate insulating film 14, and a semiconductor layer 15 of each of the active elements are disposed.

Each of the TFTs 18 is composed of the semiconductor layer 15, a drain electrode 16, and a source electrode 17. An insulating film 19 is disposed on the TFTs 18. An anode 21 constituting an organic light-emitting device 26 and the source electrode 17 are connected through a contact hole 20 provided in the insulating film 19. The form of electrical connection between the electrodes (anode 21 and cathode 23) included in the organic light-emitting device 26 and the electrodes (source electrode 17 and drain electrode 16) included in the TFT is not limited to that illustrated in FIG. 1B. That is, any form may be employed as long as one of the anode and the cathode is electrically connected to one of the source electrode and the drain electrode of the TFT.

In the display apparatus 100 illustrated in FIG. 1B, an organic compound layer is illustrated as a single layer. Alternatively, the organic compound layer 22 may be composed of a plurality of layers. A first protective layer 24 and a second protective layer 25 for reducing degradation of the organic light-emitting device 26 are disposed over the cathode 23. Although transistors are used as the switching elements in the display apparatus 100 illustrated in FIG. 1B, other switching elements may be used instead of the transistors.

The transistors used in the display apparatus 100 illustrated in FIG. 1B are not limited to transistors that use a single-crystal silicon wafer and may also be thin-film transistors including an active layer on an insulating surface of a substrate. Examples of the material of the active layer include single-crystal silicon; non-single-crystal silicon such as amorphous silicon and microcrystalline silicon; and non-single-crystal oxide semiconductors such as indium zinc oxide and indium gallium zinc oxide.

The transistors included in the display apparatus 100 illustrated in FIG. 1B may be formed inside a substrate, such as a silicon substrate. The expression “formed inside a substrate” means that transistors are produced by processing a substrate, such as a silicon substrate. In other words, having transistors inside a substrate can be considered that a substrate and transistors are integrally formed.

In the organic light-emitting device, the emission luminance is controlled by the TFTs, which are one example of switching elements, and an image is displayed at respective emission luminance levels by arranging a plurality of organic light-emitting devices in a plane. The switching elements are not limited to TFTs and may be transistors formed of low-temperature polysilicon or active-matrix drivers formed on a substrate, such as a silicon substrate. The expression “on or inside a substrate” can also be referred to as “within the substrate”. Whether transistors are formed within a substrate or TFTs are used is selected on the basis of the size of a display unit. For example, when the display unit has a size of about 0.5 inches, organic light-emitting devices are preferably disposed on a silicon substrate.

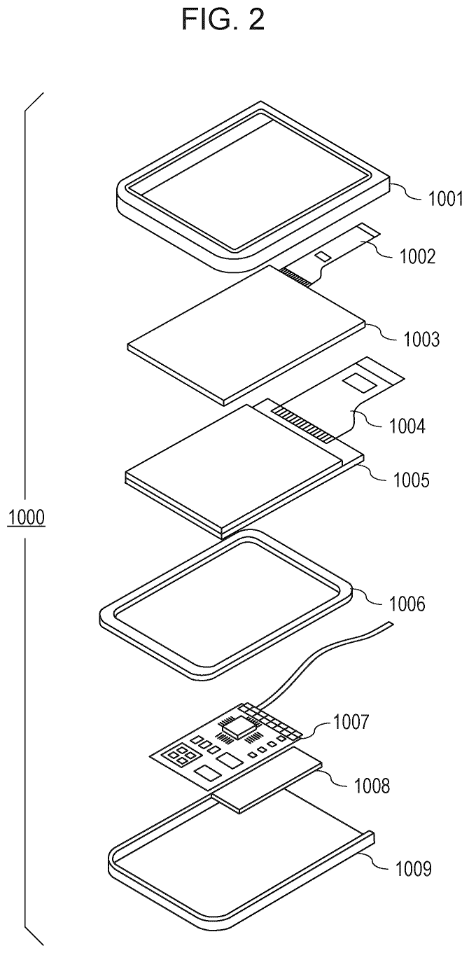

FIG. 2 is a schematic view illustrating an example of a display apparatus. A display apparatus 1000 includes an upper cover 1001 and a lower cover 1009, and a touch panel 1003, a display panel 1005, a frame 1006, a circuit substrate 1007, and a battery 1008 that are disposed between the upper cover 1001 and the lower cover 1009. The touch panel 1003 and the display panel 1005 are connected to flexible printed circuits FPC 1002 and 1004, respectively. Transistors are printed on the circuit substrate 1007. When the display apparatus is portable equipment, the battery 1008 is provided. The battery 1008 may be installed in another position.

The display apparatus may include a color filter having red, green, and blue portions. The red, green, and blue portions of the color filter may be arranged in a delta arrangement, a stripe arrangement, or a mosaic arrangement.

The display apparatus can be used for a display unit of a portable terminal. In such a case, the display apparatus may have both a display function and an operation function. Examples of the portable terminal include mobile phones such as smart phones, tablets, and head-mounted displays.

The display apparatus can be used for a display unit of an imaging apparatus including an optical unit including a plurality of lenses and an imaging device configured to receive light that has passed through the optical unit. The imaging apparatus may include a display unit configured to display information acquired by the imaging device. The display unit may be a display unit exposed to the outside of the imaging apparatus or a display unit disposed in a viewfinder. The imaging apparatus may be a digital camera or a digital camcorder. The imaging apparatus can also be referred to as a photoelectric conversion apparatus.

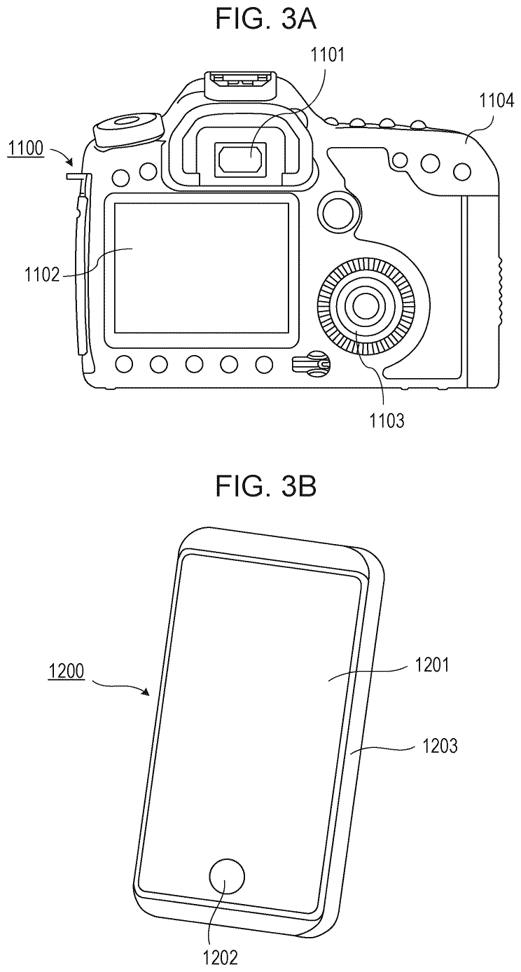

FIG. 3A is a schematic view illustrating an example of an imaging apparatus. An imaging apparatus 1100 includes a viewfinder 1101, a rear surface display 1102, an operation unit 1103, and a housing 1104. A display apparatus can be used as the viewfinder 1101. In such a case, the display apparatus may display not only an image to be captured but also, for example, environmental information and imaging instructions. The environmental information may include, for example, the intensity of external light, the direction of external light, the moving speed of the photographic subject, and the possibility that the photographic subject may hide behind an obstacle.

Since the suitable timing for capturing an image is a very short period of time, information can be preferably displayed quickly. Since an organic light-emitting device has a high response speed, a display apparatus that uses the organic light-emitting device according to the present disclosure can be suitably applied. The imaging apparatus 1100 includes an optical unit not illustrated in the drawing.

The optical unit includes a plurality of lenses and is configured to focus an image on an imaging device contained in the housing 1104. The focal point of the plurality of lenses can be adjusted by adjusting their relative positions. This operation can also be performed automatically.

FIG. 3B is a schematic view of an example of electronic equipment. Electronic equipment 1200 includes a display unit 1201, an operation unit 1202, and a housing 1203. The housing 1203 includes therein circuits, a printed circuit board having the circuits, a battery, a communication unit, and the like. The operation unit 1202 may be a button or a touch panel-type responsive unit. The operation unit 1202 may be a biometric authentication unit configured to, for example, recognize the fingerprints and release the lock. The electronic equipment that includes a communication unit can also be referred to as communication equipment. The electronic equipment 1200 may include a lens and an imaging device and thereby further have a camera function. In such a case, an image captured by the camera function is displayed on the display unit 1201. Examples of the electronic equipment 1200 include smart phones and notebook computers.

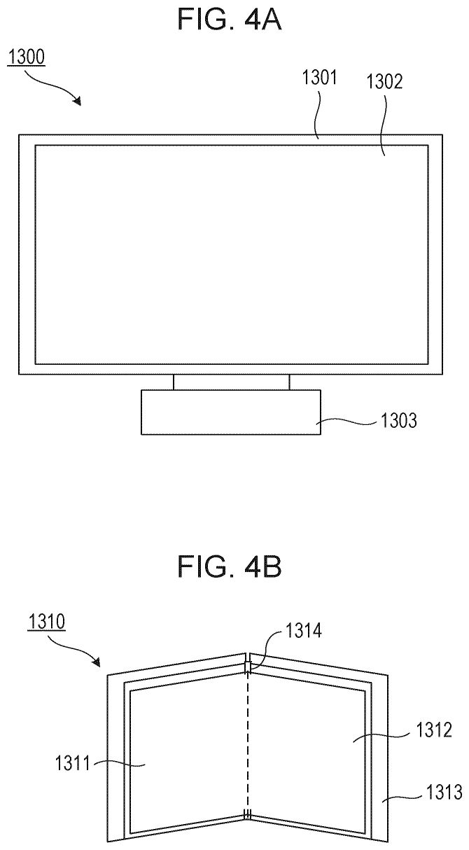

FIGS. 4A and 4B are schematic views each illustrating an example of a display apparatus. FIG. 4A illustrates a display apparatus such as a television monitor or a PC monitor. A display apparatus 1300 includes a frame 1301, a display unit 1302, and a base 1303 that supports the display unit 1302. A light-emitting apparatus is used as the display unit 1302. The base 1303 is not limited to the form illustrated in FIG. 4A. The lower side of the frame 1301 may also function as the base. The frame 1301 and the display unit 1302 may be curved. The radius of curvature thereof is preferably 5,000 mm or more and 6,000 mm or less.

FIG. 4B is a schematic view illustrating another example of the display apparatus. A display apparatus 1310 illustrated in FIG. 4B is configured to be foldable and is a so-called foldable display apparatus. The display apparatus 1310 has a first display unit 1311, a second display unit 1312, a housing 1313, and a folding point 1314. Light-emitting apparatuses can be used as the first display unit 1311 and the second display unit 1312. The first display unit 1311 and the second display unit 1312 may be a single display apparatus without a joint. The first display unit 1311 and the second display unit 1312 can be separated at the folding point. The first display unit 1311 and the second display unit 1312 may respectively display different images or may display a single image.

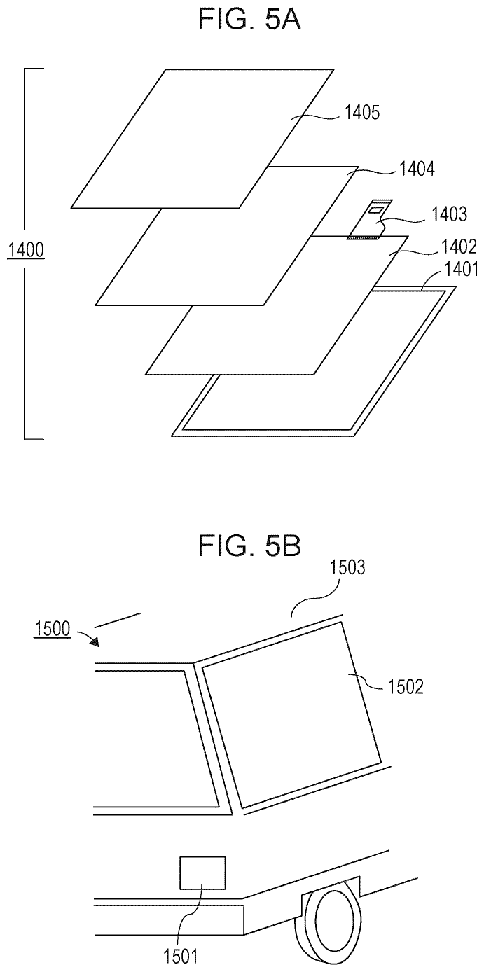

FIG. 5A is a schematic view illustrating an example of an illumination apparatus. An illumination apparatus 1400 includes a housing 1401, a light source 1402, a circuit substrate 1403, an optical filter 1404, and a light diffusion unit 1405. An organic light-emitting device can be used as the light source 1402. The optical filter 1404 may be a filter that improves the color rendering properties of the light source. The light diffusion unit 1405 can effectively diffuse light emitted from the light source and allow the light to reach a wide range, for example, for lighting up. The optical filter 1404 and the light diffusion unit 1405 may be disposed on the light-emitting side of the illumination. A cover may be optionally disposed on the outermost portion.

The illumination apparatus is, for example, an apparatus that illuminates the interior of a room and includes a light source and a member configured to transmit light emitted from the light source. The illumination apparatus may emit light of a color such as white, natural white, or any other color from blue to red. Here, “white” has a color temperature of 4,200 K, and “natural white” has a color temperature of 5,000 K. The illumination apparatus may include a light modulating circuit configured to modulate such light. The illumination apparatus may include an organic light-emitting device and a power supply circuit connected thereto. The power supply circuit is a circuit configured to convert an AC voltage into a DC voltage. The illumination apparatus may include a light diffusion unit or a color filter as the member configured to transmit light emitted from the light source. The illumination apparatus may include a heat dissipation unit. The heat dissipation unit dissipates heat in the apparatus to the outside of the apparatus and may be formed of, for example, a metal having a high specific heat or liquid silicone.

FIG. 5B is a schematic view of an automobile that is an example of a moving object. The automobile has a tail lamp that is an example of a lighting fixture. An automobile 1500 has a tail lamp 1501, and the tail lamp may light up when, for example, the brakes are applied.

The tail lamp 1501 may include an organic light-emitting device. The tail lamp 1501 may include a protective member that protects the organic light-emitting device. A protective member composed of any material that has high strength to a certain extent and is transparent can be suitably used as the protective member. In particular, the protective member is preferably composed of polycarbonate. The polycarbonate may be mixed with a furandicarboxylic acid derivative, an acrylonitrile derivative, or the like.

The automobile 1500 may include a car body 1503 and a window 1502 attached to the car body 1503. The window 1502 may be a transparent display unless it is a window for checking the front and rear of the automobile. The transparent display may include an organic light-emitting device. In such a case, the constituent materials of the electrodes of the organic light-emitting device and the like are formed of transparent members.

The moving object may be, for example, a ship, an aircraft, or a drone. The moving object may include a body and a lighting fixture attached to the body. The lighting fixture may emit light to indicate the position of the body. The lighting fixture includes an organic light-emitting device.

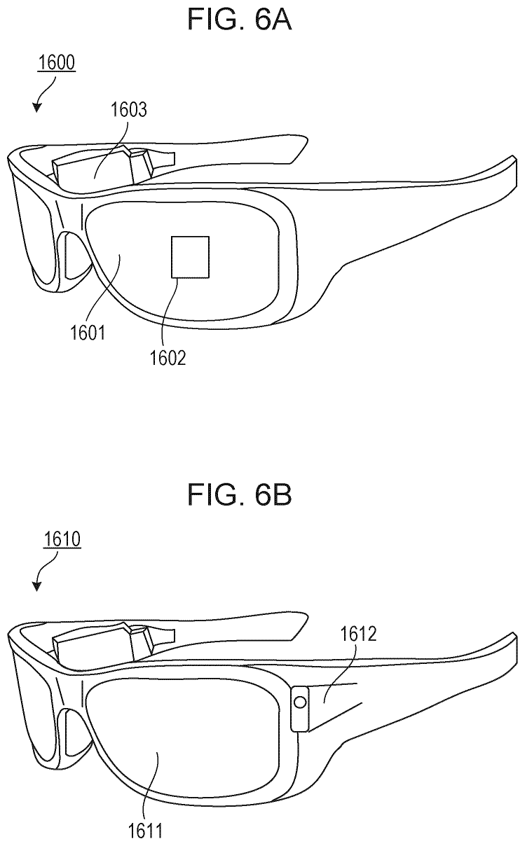

Application examples of the display apparatuses will be described with reference to FIGS. 6A and 6B. The display apparatuses are applicable to systems that can be worn as wearable devices, such as smart glasses, head-mounted displays, and smart contact lenses. An imaging and display apparatus used in such an application example includes an imaging apparatus that can photoelectrically convert visible light and a display apparatus that can emit visible light.

Glasses 1600 (smart glasses) will be described with reference to FIG. 6A. An imaging apparatus 1602 such as a complementary metal-oxide semiconductor (CMOS) sensor or a single-photon avalanche diode (SPAD) is disposed on the front side of a lens 1601 of the glasses 1600. A display apparatus is disposed on the back side of the lens 1601. The glasses 1600 further include a control unit 1603. The control unit 1603 functions as a power supply that supplies electric power to the imaging apparatus 1602 and the display apparatus. The control unit 1603 controls the operation of the imaging apparatus 1602 and the display apparatus. The lens 1601 includes an optical system for focusing light on the imaging apparatus 1602.

Glasses 1610 (smart glasses) will be described with reference to FIG. 6B. The glasses 1610 have a control unit 1612, and the control unit 1612 includes an imaging apparatus corresponding to the imaging apparatus 1602 and a display apparatus. A lens 1611 includes an optical system for projecting light emitted from the imaging apparatus and the display apparatus in the control unit 1612, and an image is projected on the lens 1611. The control unit 1612 functions as a power supply that supplies electric power to the imaging apparatus and the display apparatus and controls the operation of the imaging apparatus and the display apparatus. The control unit may have a gaze detection unit that detects the gaze of the wearer. Infrared rays may be used to detect the gaze. An infrared light-emitting unit emits infrared light toward an eyeball of the user who is gazing at a displayed image. Reflection of the infrared light from the eyeball is detected by an imaging unit including a light-receiving element to capture an image of the eyeball. A reducing unit configured to reduce light from the infrared light-emitting unit to a display unit in plan view is provided to reduce degradation of the image quality.

The glasses 1610 detect the gaze of the user for the displayed image from the image of the eyeball captured with the infrared light. Any publicly known method is applicable to the gaze detection using the captured image of the eyeball. As one example, a gaze detection method based on the Purkinje image formed by reflection of irradiation light on the cornea can be employed. More specifically, a gaze detection process based on a pupil-corneal reflection method is performed.

The gaze of the user is detected by calculating a gaze vector that indicates the direction (rotation angle) of the eyeball on the basis of the image of the pupil and the Purkinje image included in the captured image of the eyeball using the pupil-corneal reflection method.

The display apparatus may include an imaging apparatus including a light-receiving element, and may control a displayed image of the display apparatus on the basis of the gaze information of the user from the imaging apparatus. Specifically, the display apparatus determines a first display region at which the user gazes and a second display region other than the first display region on the basis of the gaze information. The first display region and the second display region may be determined by the control unit of the display apparatus or may be determined by receiving those determined by an external control unit. In the display region of the display apparatus, the display resolution of the first display region may be controlled to be higher than the display resolution of the second display region. In other words, the resolution of the second display region may be lower than that of the first display region.

The display region includes a first display region and a second display region different from the first display region. A region with higher priority is determined from the first display region and the second display region on the basis of the gaze information. The first display region and the second display region may be determined by the control unit of the display apparatus or may be determined by receiving those determined by an external control unit. The resolution of the region with higher priority may be controlled to be higher than the resolution of the region other than the region with higher priority. In other words, the resolution of a region with relatively low priority may be low.

Artificial intelligence (AI) may be used to determine the first display region or the region with higher priority. The AI may be a model configured to estimate the angle of the gaze and the distance to a target object at the end of the gaze from the image of the eyeball by using, as teaching data, the image of the eyeball and the direction in which the eyeball in the image was actually gazing. The AI program may be stored in the display apparatus, the imaging apparatus, or an external apparatus. When the AI program is stored in an external apparatus, the AI program is transmitted through communication to the display apparatus. In the case of controlling the display on the basis of visual recognition detection, the display apparatus according to the present disclosure can be preferably applied to smart glasses further including an imaging apparatus that captures an external image. The smart glasses can display the captured external information in real time.

As described above, the use of an apparatus using the organic light-emitting device according to the present disclosure enables a stable display for a long time with good image quality. Furthermore, it is possible to achieve both good outdoor visibility and power-saving display due to high-efficiency and high-luminance light output.

### EXAMPLES

Examples will be described below. However, the present disclosure is not limited to these Examples.

### Synthesis Examples

Methods for synthesizing example compound 1, comparative example compound 1, and comparative example compound 2 will be described below.

Method for Synthesizing Example Compound 1 Synthesis of Tetradentate Ligand Related to Example Compound 1

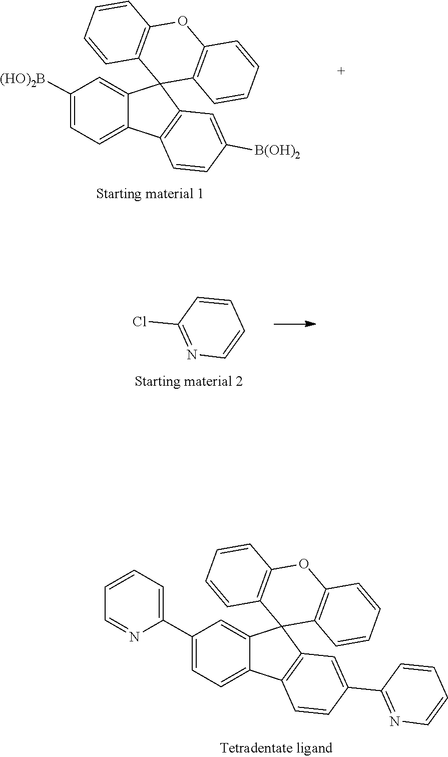 [SMILES: OB(O)c1ccc2c(c1)C1(c3ccccc3Oc3ccccc31)c1cc(B(O)O)ccc1-2 ; Clc1ccccn1 ; c1ccc(-c2ccc3c(c2)C2(c4ccccc4Oc4ccccc42)c2cc(-c4ccccn4)ccc2-3)nc1]

Into a 100 mL three-necked round-bottom flask, 1.26 g (3 mmol, 1.0 eq) of starting material 1, 1.42 g (3.0 eq) of 2-chloropyridine (starting material 2), 35.0 mg (0.03 eq) of tetrakis(triphenylphosphine) palladium (0), and 950 mg (3.0 eq) of sodium carbonate were weighed, and degassing under reduced pressure and purging with Ar were performed five times. After degassing under reduced pressure and purging with nitrogen were sufficiently performed, 20 mL of toluene, 5.0 mL of ethanol, and 3.0 mL of water were added in a nitrogen atmosphere, and the resulting reaction mixture was stirred under reflux at 74° C. for eight hours. Subsequently, heating was stopped to return the reaction mixture to room temperature. Extraction was performed three times with toluene, organic solvent layers were then gathered, anhydrous sodium sulfate was added thereto, and the resulting solution was left to stand for a while. The sodium sulfate was removed by filtration, and the solution was concentrated under reduced pressure. The obtained oil was subjected to silica-gel short column chromatography using toluene as an eluent, and a fraction containing a target substance was collected and concentrated under reduced pressure. The obtained oil was subjected to silica-gel column chromatography using heptane-toluene as an eluent, and a fraction containing a tetradentate ligand was collected and concentrated under reduced pressure. The tetradentate ligand was confirmed by MALDI-MS (m/z=486.17).

Tetradentate ligands related to example compounds 10, 17, 27, 29, 30, 46, 50, and 51, comparative example compound 1, and comparative example compound 2 were each synthesized by a method similar to that of the tetradentate ligand related to example compound 1. Table 1 below shows structural formulas of starting material 1 and starting material 2 used in the synthesis, the structural formula of each tetradentate ligand, the yield, and identification data.

TABLE 1

| | | | Tetradentate ligand | | |
|---|---|---|---|---|---|
| | | | | | MALDI- |
| | | | | Yield | MS |
| | Starting material 1 | Starting material 2 | Structural formula | [g] | m/z |
| Example compound 1 | 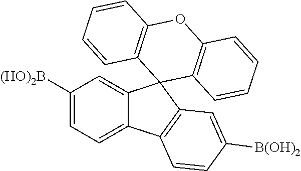 [SMILES: OB(O)c1ccc2c(c1)C1(c3ccccc3Oc3ccccc31)c1cc(B(O)O)ccc1-2] | 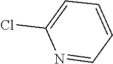 | 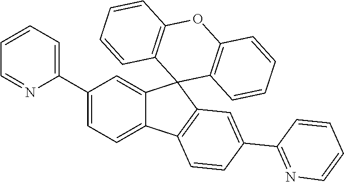 [SMILES: c1ccc(-c2ccc3c(c2)C2(c4ccccc4Oc4ccccc42)c2cc(-c4ccccn4)ccc2-3)nc1] | 1.16 | 486.17 |
| Example compound 10 | 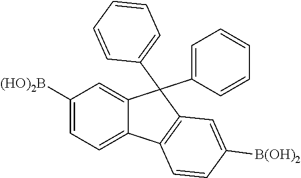 [SMILES: OB(O)c1ccc2c(c1)C(c1ccccc1)(c1ccccc1)c1cc(B(O)O)ccc1-2] | 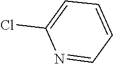 | 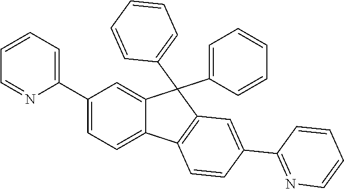 [SMILES: c1ccc(C2(c3ccccc3)c3cc(-c4ccccn4)ccc3-c3ccc(-c4ccccn4)cc32)cc1] | 1.13 | 472.19 |
| Example compound 17 | 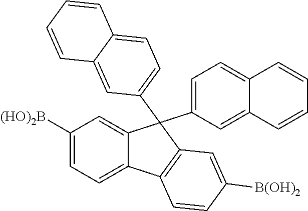 [SMILES: OB(O)c1ccc2c(c1)C(c1ccc3ccccc3c1)(c1ccc3ccccc3c1)c1cc(B(O)O)ccc1-2] | 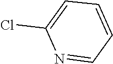 | 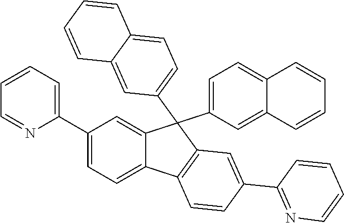 [SMILES: c1ccc(-c2ccc3c(c2)C(c2ccc4ccccc4c2)(c2ccc4ccccc4c2)c2cc(-c4ccccn4)ccc2-3)nc1] | 1.37 | 572.23 |
| Example compound 27 | 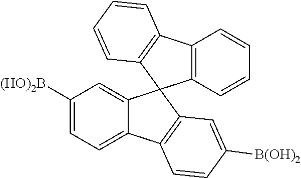 [SMILES: OB(O)c1ccc2c(c1)C1(c3ccccc3-c3ccccc31)c1cc(B(O)O)ccc1-2] | 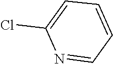 | 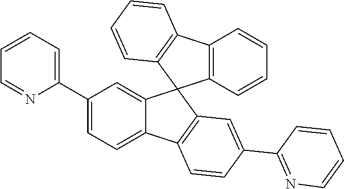 [SMILES: c1ccc(-c2ccc3c(c2)C2(c4ccccc4-c4ccccc42)c2cc(-c4ccccn4)ccc2-3)nc1] | 1.13 | 470.18 |
| Example compound 29 | 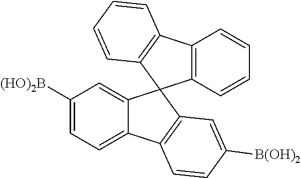 [SMILES: OB(O)c1ccc2c(c1)C1(c3ccccc3-c3ccccc31)c1cc(B(O)O)ccc1-2] | 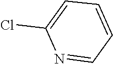 | 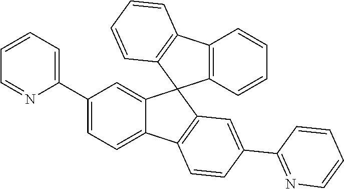 [SMILES: c1ccc(-c2ccc3c(c2)C2(c4ccccc4-c4ccccc42)c2cc(-c4ccccn4)ccc2-3)nc1] | 1.13 | \|470.18 |
| Example compound 30 | 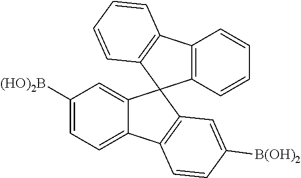 [SMILES: OB(O)c1ccc2c(c1)C1(c3ccccc3-c3ccccc31)c1cc(B(O)O)ccc1-2] | 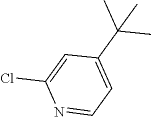 | 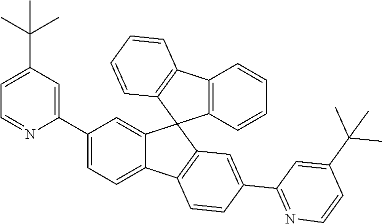 [SMILES: CC(C)(C)c1ccnc(-c2ccc3c(c2)C2(c4ccccc4-c4ccccc42)c2cc(-c4cc(C(C)(C)C)ccn4)ccc2-3)c1] | 1.40 | 582.30 |
| Example compound 46 | 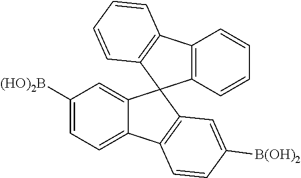 [SMILES: OB(O)c1ccc2c(c1)C1(c3ccccc3-c3ccccc31)c1cc(B(O)O)ccc1-2] | 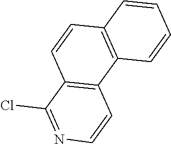 [SMILES: Clc1nccc2c1ccc1ccccc12] | 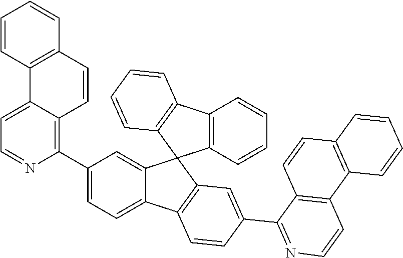 [SMILES: c1ccc2c(c1)-c1ccccc1C21c2cc(-c3nccc4c3ccc3ccccc34)ccc2-c2ccc(-c3nccc4c3ccc3ccccc34)cc21] | 1.61 | 670.24 |
| Example compound 50 | 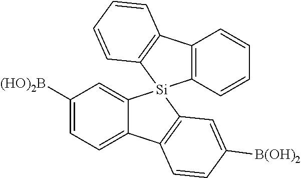 [SMILES: OB(O)c1ccc2c(c1)[Si]1(c3ccccc3-c3ccccc31)c1cc(B(O)O)ccc1-2] | 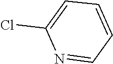 | 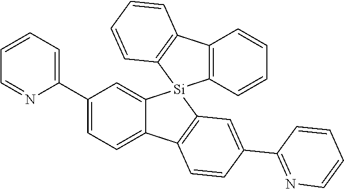 [SMILES: c1ccc(-c2ccc3c(c2)[Si]2(c4ccccc4-c4ccccc42)c2cc(-c4ccccn4)ccc2-3)nc1] | 1.17 | 486.16 |
| Example compound 51 | 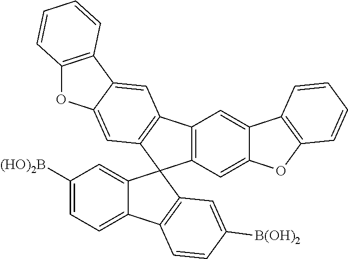 [SMILES: OB(O)c1ccc2c(c1)C1(c3cc(B(O)O)ccc3-2)c2cc3oc4ccccc4c3cc2-c2cc3c(cc21)oc1ccccc13] | 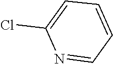 | 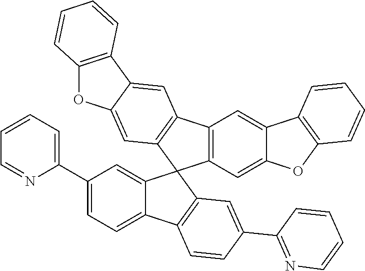 [SMILES: c1ccc(-c2ccc3c(c2)C2(c4cc(-c5ccccn5)ccc4-3)c3cc4oc5ccccc5c4cc3-c3cc4c(cc32)oc2ccccc24)nc1] | 1.56 | 650.20 |
| Comparative example compound 1 | 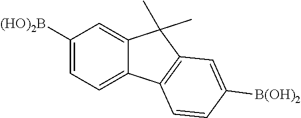 [SMILES: CC1(C)c2cc(B(O)O)ccc2-c2ccc(B(O)O)cc21] | 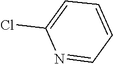 | 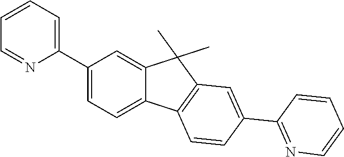 [SMILES: CC1(C)c2cc(-c3ccccn3)ccc2-c2ccc(-c3ccccn3)cc21] | 0.84 | 348.16 |
| Comparative example compound 2 | 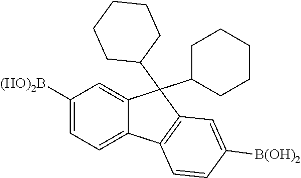 [SMILES: OB(O)c1ccc2c(c1)C(C1CCCCC1)(C1CCCCC1)c1cc(B(O)O)ccc1-2] | 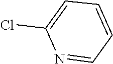 | 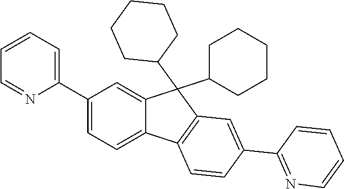 [SMILES: c1ccc(-c2ccc3c(c2)C(C2CCCCC2)(C2CCCCC2)c2cc(-c4ccccn4)ccc2-3)nc1] | 1.16 | 484.29 |

### Synthesis of Intermediate Related to Example Compound 1

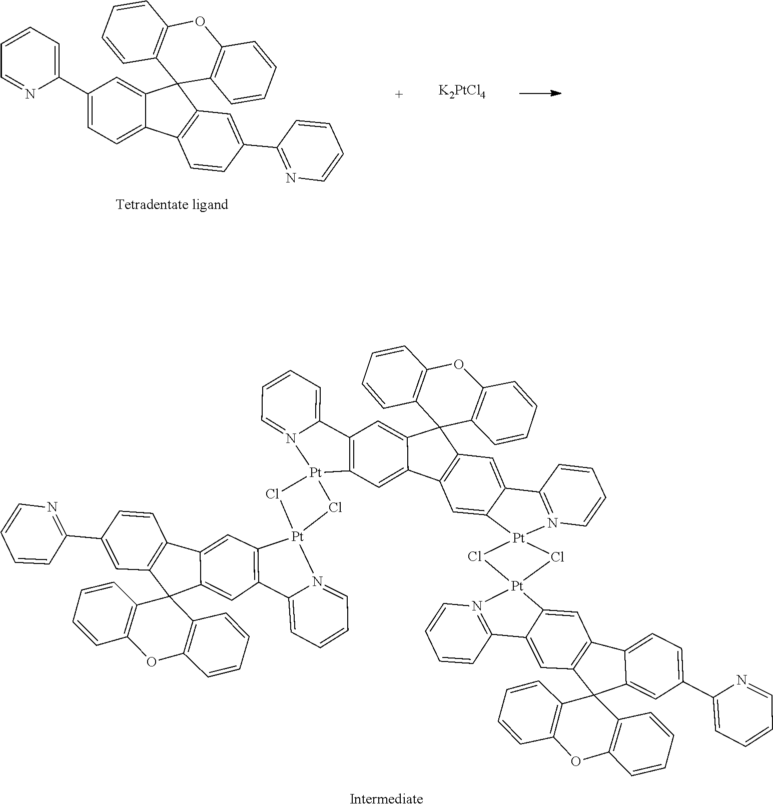

To a mixed solvent (20 mL of ethoxyethanol and 5 mL of water), the tetradentate ligand [1.16 g, 2.40 mmol] and K₂PtC₁₄ [1.86 g, 1.5 eq] were added, and the resulting reaction mixture was heated at 90° C. for 10 hours with stirring under a nitrogen stream. A dark red precipitate was filtered and washed with methanol to obtain a dark yellow powder. For simplicity of description, the reaction scheme shows a tetranuclear complex; however, a hexanuclear or higher polynuclear complex may be generated. The synthesis proceeded to the next synthesis step without identification.

Intermediates related to example compounds 10, 17, 27, 29, 30, 46, 50, and 51, comparative example compound 1, and comparative example compound 2 were each synthesized by a method similar to that of the intermediate related to example compound 1.

### Synthesis of Final Product Related to Example Compound 1

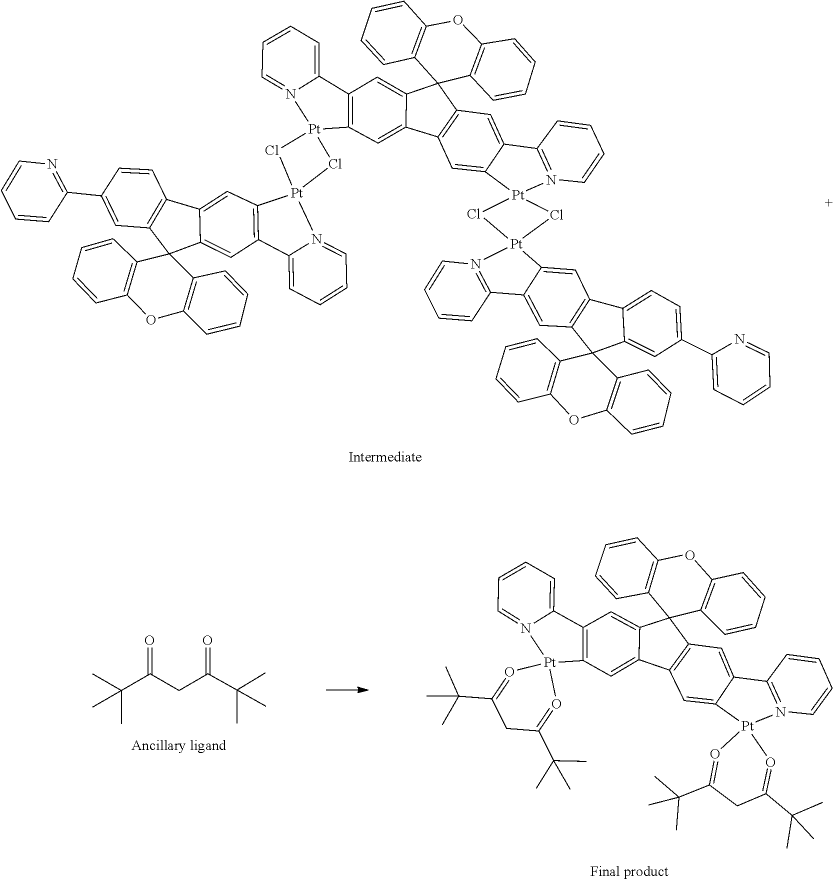

To 10 mL of ethoxyethanol, the above intermediate [0.25 mmol (assumed to be a tetranuclear complex)] and an ancillary ligand [368 mg, 2 mmol] were added, and the resulting reaction mixture was stirred under reflux at 90° C. for five hours under a nitrogen stream. Subsequently, heating was stopped to return the reaction mixture to room temperature. Extraction was performed three times with dichloromethane, organic solvent layers were then gathered, anhydrous sodium sulfate was added thereto, and the resulting solution was left to stand for a while. The sodium sulfate was removed by filtration, and the solution was concentrated under reduced pressure. The obtained oil was subjected to silica-gel short column chromatography using toluene as an eluent, and a fraction containing a target substance was collected and concentrated under reduced pressure. The obtained oil was subjected to silica-gel column chromatography using heptane-toluene as an eluent, and a fraction containing a final product was collected and concentrated under reduced pressure. The final product was confirmed by MALDI-MS (m/z=1242.38).

Final products related to example compounds 10, 17, 27, 29, 30, 46, 50, and 51, comparative example compound 1, and comparative example compound 2 were each synthesized by a method similar to that of the final product related to example compound 1. Tables 2-1 and 2-2 below show structural formulas of the intermediate and the ancillary ligand used in the synthesis, the structural formula of each final product, the yield, and identification data.

TABLE 2-1

| | | | Final product | | |
|---|---|---|---|---|---|
| | | | | | MALDI- |
| | | Ancillary | | Yield | MS |
| | Intermediate | ligand | Structural formula | [mg] | m/z |
| Example compound 1 | 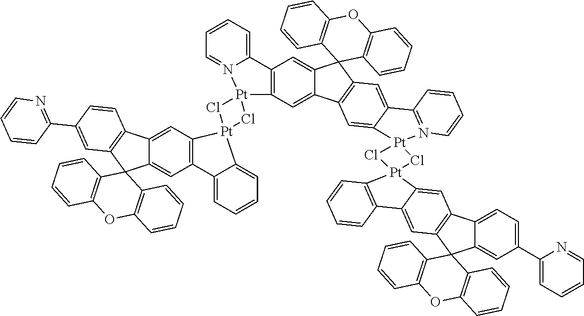 | 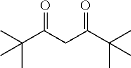 | 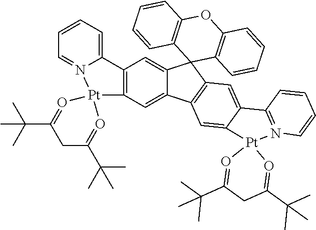 | 248 | 1242.38 |
| Example compound 10 | 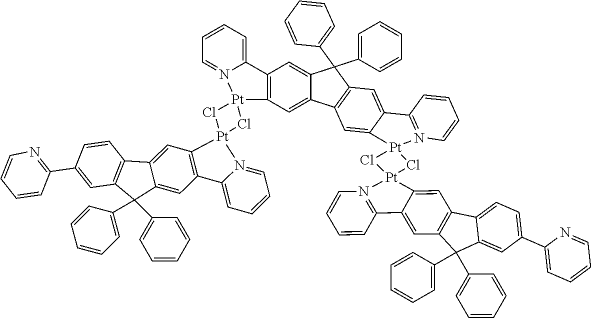 | 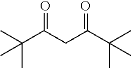 | 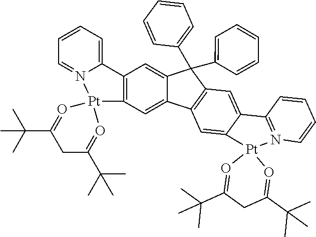 | 245 | 1227.40 |
| Example compound 17 | 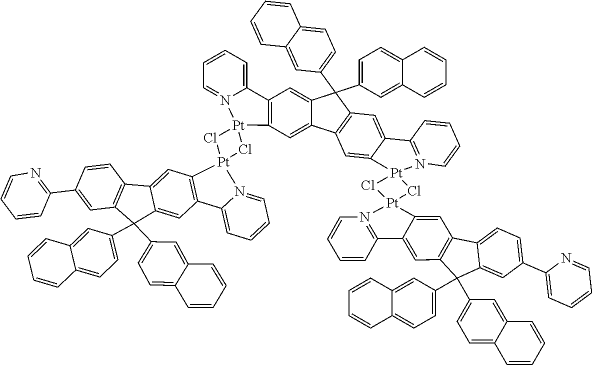 | 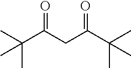 | 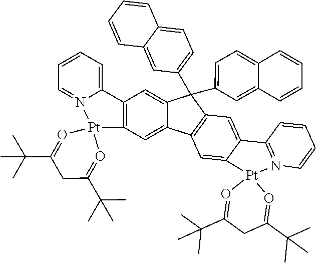 | 265 | 1327.43 |
| Example compound 27 | 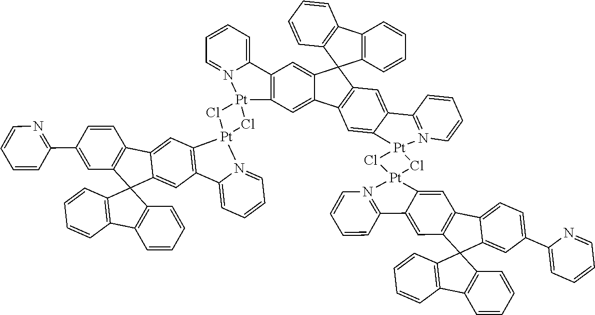 | 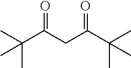 | 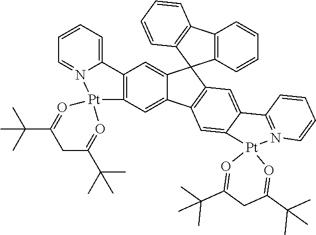 | 245 | 1225.38 |
| Example compound 29 | 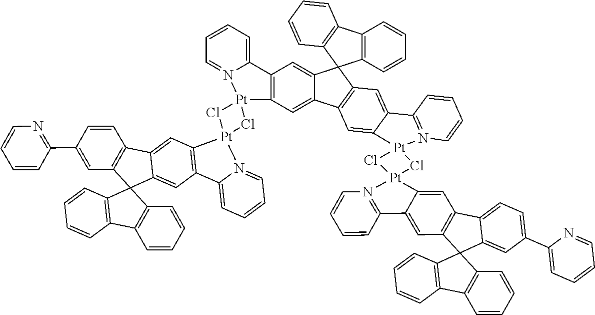 | 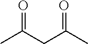 | 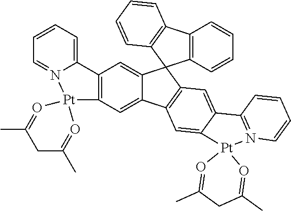 | 211 | 1057.19 |
| Example compound 30 | 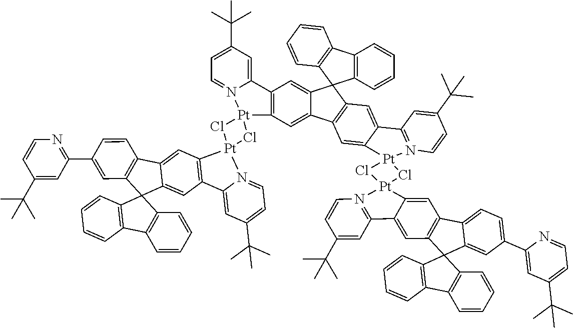 | 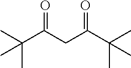 | 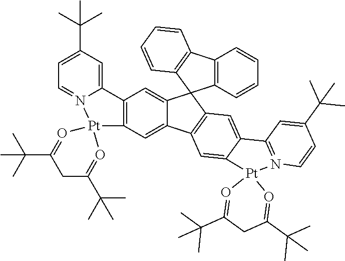 | 268 | 1337.51 |

TABLE 2-2

| | | | Final product | | |
|---|---|---|---|---|---|
| | | | | | MALDI- |
| | | Ancillary | | Yield | MS |
| | Intermediate | ligand | Structural formula | [mg] | m/z |
| Example compound 46 | 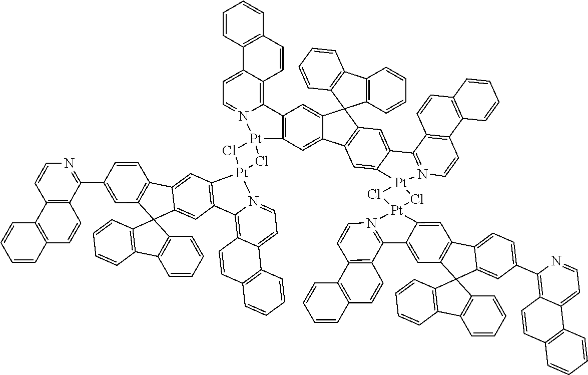 | 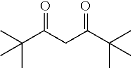 | 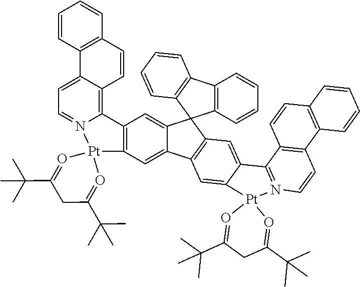 | 285 | 1425.45 |
| Example compound 50 | 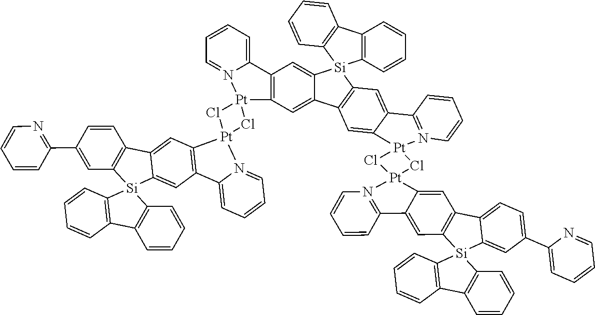 | 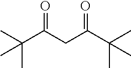 | 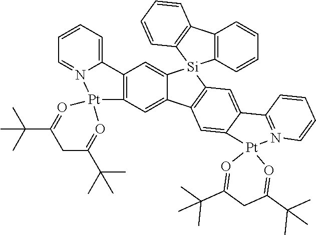 | 248 | 1241.36 |
| Example compound 51 | 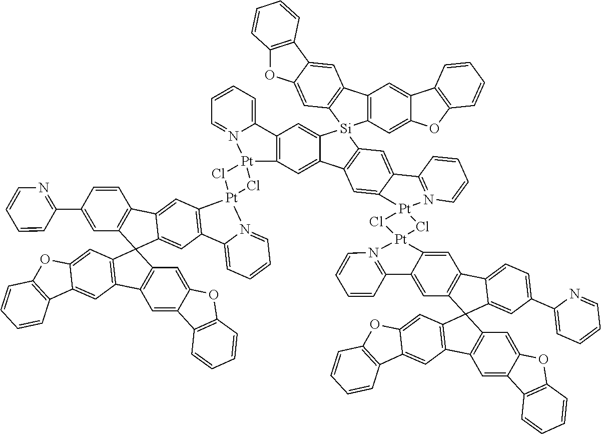 | 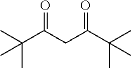 | 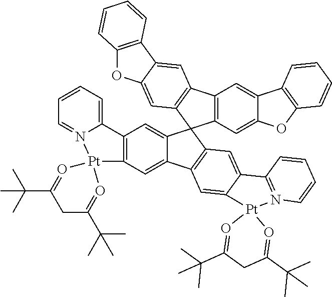 | 281 | 1405.40 |
| Comparative example compound 1 | 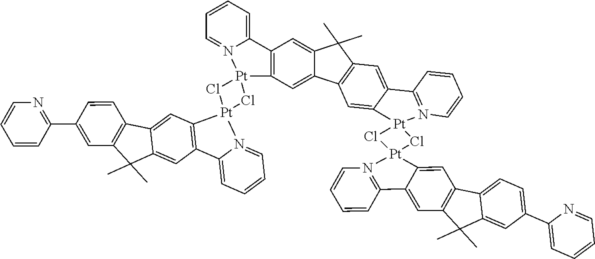 | 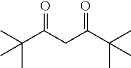 | 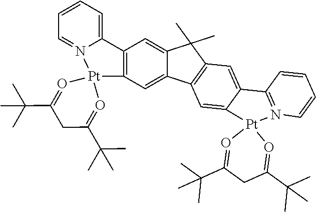 | 221 | 1103.37 |
| Comparative example compound 2 | 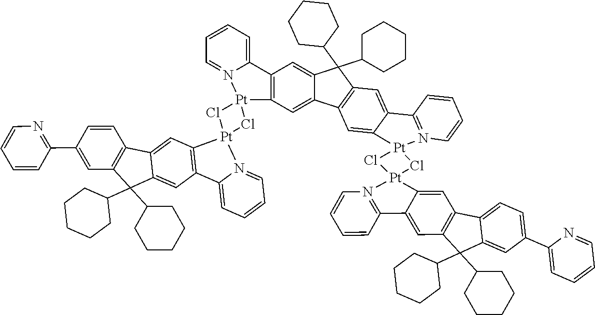 | 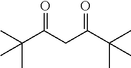 | 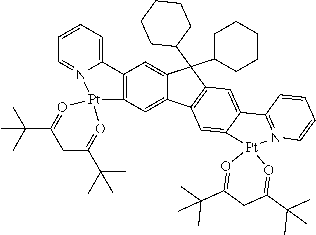 | 248 | 1239.49 |

### Preparation of Liquid Light-Emitting Composition

Components (unit: % by mass) shown in Table 3 were mixed and sufficiently stirred for dissolution. The resulting solution was then filtered under pressure through a filter having a pore size of 0.2 μm to prepare each light-emitting composition.
Organometallic complex (of the type shown in Table 3): amount shown in Table 3 (% by mass)
Host material (EM33): amount shown in Table 3 (% by mass)·
Organic solvent (toluene): 99.0 (% by mass)

TABLE 3

| | | Amount | Amount of |
|---|---|---|---|
| Light- | | used | host used |
| emitting | | (% by | (% by |
| composition | Organometallic complex | mass) | mass) |
| No. 1 | Example compound 1 | 1.00 | 0.00 |
| No. 2 | Example compound 1 | 0.50 | 0.50 |
| No. 3 | Example compound 1 | 0.05 | 0.95 |
| No. 4 | Example compound 10 | 1.00 | 0.00 |
| No. 5 | Example compound 10 | 0.50 | 0.50 |
| No. 6 | Example compound 10 | 0.05 | 0.95 |
| No. 7 | Example compound 17 | 1.00 | 0.00 |
| No. 8 | Example compound 17 | 0.50 | 0.50 |
| No. 9 | Example compound 17 | 0.05 | 0.95 |
| No. 10 | Example compound 27 | 1.00 | 0.00 |
| No. 11 | Example compound 27 | 0.50 | 0.50 |
| No. 12 | Example compound 27 | 0.05 | 0.95 |
| No. 13 | Example compound 29 | 1.00 | 0.00 |
| No. 14 | Example compound 29 | 0.50 | 0.50 |
| No. 15 | Example compound 29 | 0.05 | 0.95 |
| No. 16 | Example compound 30 | 1.00 | 0.00 |
| No. 17 | Example compound 30 | 0.50 | 0.50 |
| No. 18 | Example compound 30 | 0.05 | 0.95 |
| No. 19 | Example compound 46 | 1.00 | 0.00 |
| No. 20 | Example compound 46 | 0.50 | 0.50 |
| No. 21 | Example compound 46 | 0.05 | 0.95 |
| No. 22 | Example compound 50 | 1.00 | 0.00 |
| No. 23 | Example compound 50 | 0.50 | 0.50 |
| No. 24 | Example compound 50 | 0.05 | 0.95 |
| No. 25 | Example compound 51 | 1.00 | 0.00 |
| No. 26 | Example compound 51 | 0.50 | 0.50 |
| No. 27 | Example compound 51 | 0.05 | 0.95 |
| No. 28 | Comparative example compound 1 | 1.00 | 0.00 |
| No. 29 | Comparative example compound 1 | 0.50 | 0.50 |
| No. 30 | Comparative example compound 1 | 0.05 | 0.95 |
| No. 31 | Comparative example compound 2 | 1.00 | 0.00 |
| No. 32 | Comparative example compound 2 | 0.50 | 0.50 |
| No. 33 | Comparative example compound 2 | 0.05 | 0.95 |

### Preparation of Neat Film N by Spin Coating Method

Next, thin films (neat films N) having a doping concentration of an organometallic complex of 100.0% by mass were formed by a spin coating method. Film forming conditions are as follows.
Coating liquid: The light-emitting composition Nos. 1, 4, 7, 10, 13, 16, 19, 22, 25, 28, and 31 shown in Table 3
Spin coating conditions: 3,000 rpm for 60 seconds
Annealing conditions: 110° C. for 10 minutes
Film thickness: 10 nm

### Preparation of Doped Film D1 and Doped Film D2 by Spin Coating Method

Next, thin films (doped films D1) having a doping concentration of an organometallic complex of 5.0% by mass and thin films (doped films D2) having a doping concentration of an organometallic complex of 50.0% by mass were formed by a spin coating method. Film forming conditions are as follows.
Coating liquid: The light-emitting composition Nos. 2, 3, 5, 6, 8, 9, 11, 12, 14, 15, 17, 18, 20, 21, 23, 24, 26, 27, 29, 30, 32, and 33 shown in Table 3
Spin coating conditions: 3,000 rpm for 60 seconds
Annealing conditions: 110° C. for 10 minutes
Film thickness: 10 nm

### Preparation of Neat Film N by Vapor Deposition Method

Example compound 1 was deposited on a quartz substrate by a vapor deposition method at a degree of vacuum of 5×10⁻⁶ Pa or less to prepare a thin film (neat film N) having a doping concentration of example compound 1 of 100.0% by mass. The film thickness of the light-emitting layer is 10 nm. Neat films N of the example compounds 10, 17, 27, 29, 30, 46, 50, and 51, comparative example compound 1, and comparative example compound 2 were prepared in the same manner as described above.

### Formation of Doped Film D1 and Doped Film D2 by Vapor Deposition Method

Example compound 1 and EM33 were deposited from different evaporation sources on a quartz substrate by a vapor deposition method at a degree of vacuum of 5×10⁻⁶ Pa or less. Thus, a thin film (doped film D1) having a doping concentration of example compound 1 of 5.0% by mass and a thin film (doped film D2) having a doping concentration of example compound 1 of 50.0% by mass were each prepared to have a thickness of 10 nm. Doped films D1 and doped films D2 of the example compounds 10, 17, 27, 29, 30, 46, 50, and 51, comparative example compound 1, and comparative example compound 2 were prepared in the same manner as described above.

### EVALUATION

For each of the neat films and the doped films prepared above, the photoluminescence quantum yield of the neat film (hereinafter, also referred to as PLQY (N)), the photoluminescence quantum yield of the doped film D1 (hereinafter, also referred to as PLQY (D1)), and the photoluminescence quantum yield of the doped film D2 (hereinafter, also referred to as PLQY (D2)) were measured. The measurement conditions were as follows: excitation light: 346 nm, host light-emitting region: 400 to 550 nm, and dopant light-emitting region: 550 to 800 nm, and an absolute PL quantum yield spectrometer (trade name “C11347-01”, manufactured by Hamamatsu Photonics K. K.) was used. PLQY (N)/PLQY (D1) and PLQY (N)/PLQY (D2) were calculated from the values of PLQY (N), PLQY (D1), and PLQY (D2) determined by the above measurement, and the ratio of the photoluminescence quantum yield of the neat film to that of each of the doped films was evaluated in accordance with the evaluation criteria described below. Larger values of PLQY (N)/PLQY (D1) and PLQY (N)/PLQY (D2) mean that a decrease in the photoluminescence quantum yield due to aggregation of the organometallic complex can be further suppressed.
A: The value of PLQY (N)/PLQY (D1) or PLQY (N)/PLQY (D2) was more than 1.5.
B: The value of PLQY (N)/PLQY (D1) or PLQY (N)/PLQY (D2) was more than 1.0 and 1.5 or less.
C: The value of PLQY (N)/PLQY (D1) or PLQY (N)/PLQY (D2) was 1.0 or less.

TABLE 4

| | Organometallic | PLQY(N)/PLQY(D1) | PLQY(N)/PLQY(D2) | PLQY(N)/PLQY(D1) | PLQY(N)/PLQY(D2) |
|---|---|---|---|---|---|
| | complex | Vapor deposition method | | Spin coating method | |
| Example 1 | Example | B | B | B | B |
| | compound 1 | | | | |
| Example 2 | Example | B | B | B | B |
| | compound 10 | | | | |
| Example 3 | Example | B | B | B | B |
| | compound 17 | | | | |
| Example 4 | Example | A | A | A | A |
| | compound 27 | | | | |
| Example 5 | Example | A | A | A | A |
| | compound 29 | | | | |
| Example 6 | Example | A | A | A | A |
| | compound 30 | | | | |
| Example 7 | Example | A | A | A | A |
| | compound 46 | | | | |
| Example 8 | Example | A | A | A | A |
| | compound 50 | | | | |
| Example 9 | Example | A | A | A | A |
| | compound 51 | | | | |
| Comparative | Comparative | C | C | C | C |
| Example 1 | example | | | | |
| | compound 1 | | | | |
| Comparative | Comparative | C | C | C | C |
| Example 2 | example | | | | |
| | compound 2 | | | | |

From the above, it was found that the organometallic complexes according to the present disclosure are useful as phosphorescent materials that suppress a decrease in the photoluminescence quantum yield at high doping concentrations.

The present disclosure can provide an organometallic complex in which a decrease in the photoluminescence quantum yield due to the formation of a trap site and concentration quenching is reduced.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-006667, filed Jan. 17, 2025, which is hereby incorporated by reference herein in its entirety.

What is claimed is:

1. An organometallic complex represented by formula (1): 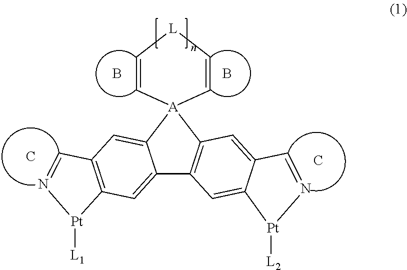
wherein A is a carbon atom or a silicon atom,
each B is independently a substituted or unsubstituted aryl ring or a substituted or unsubstituted heteroaryl ring,
L is selected from the group consisting of a carbon atom, a nitrogen atom, an oxygen atom, and a sulfur atom,
n is 0 or 1,
each C is independently a substituted or unsubstituted heteroaryl ring, and PtL₁ and PtL₂ are each independently a bidentate ligand represented by formula (3): 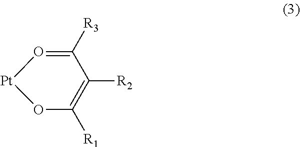
wherein R₁ to R₃ are each independently selected from the group consisting of a hydrogen atom, a deuterium atom, a halogen atom, a substituted or unsubstituted alkyl group, a substituted or unsubstituted cycloalkyl group, a substituted or unsubstituted alkoxy group, a substituted or unsubstituted aryl group, and a substituted or unsubstituted heteroaryl group.

2. The organometallic complex according to claim 1, wherein the organometallic complex is represented by formula (2): 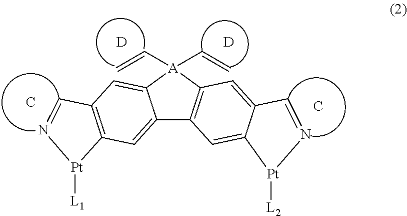
wherein each D is independently selected from the group consisting of a substituted or unsubstituted aryl ring and a substituted or unsubstituted heteroaryl ring.

3. The organometallic complex according to claim 1, wherein n is 0.

4. The organometallic complex according to claim 1, wherein R₁ and R₃ are each an alkyl group, and R₂ is a hydrogen atom.

5. The organometallic complex according to claim 2, wherein each D is a phenyl group or a naphthalene group, R₁ and R₃ are each an alkyl group, and R₂ is a hydrogen atom.

6. The organometallic complex according to claim 1, wherein the organometallic complex is represented by any one of structural formulas below:

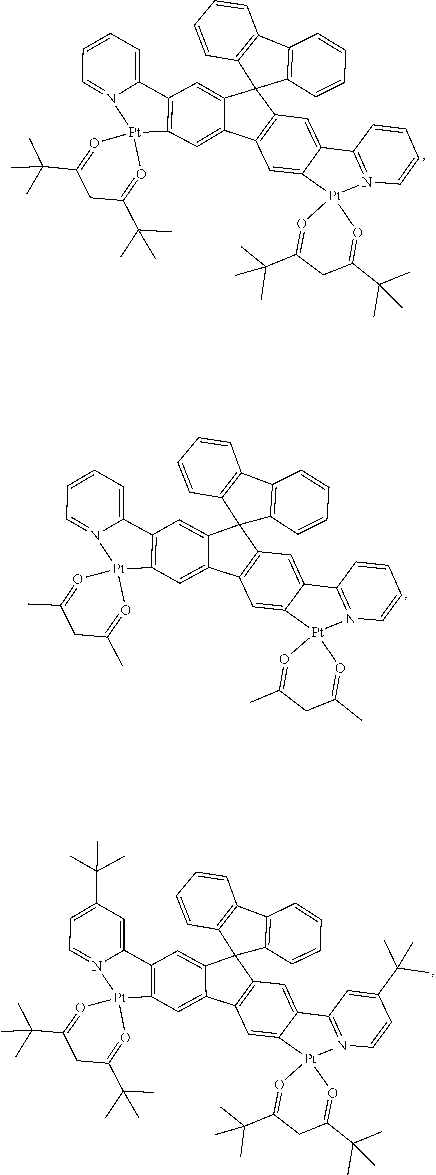

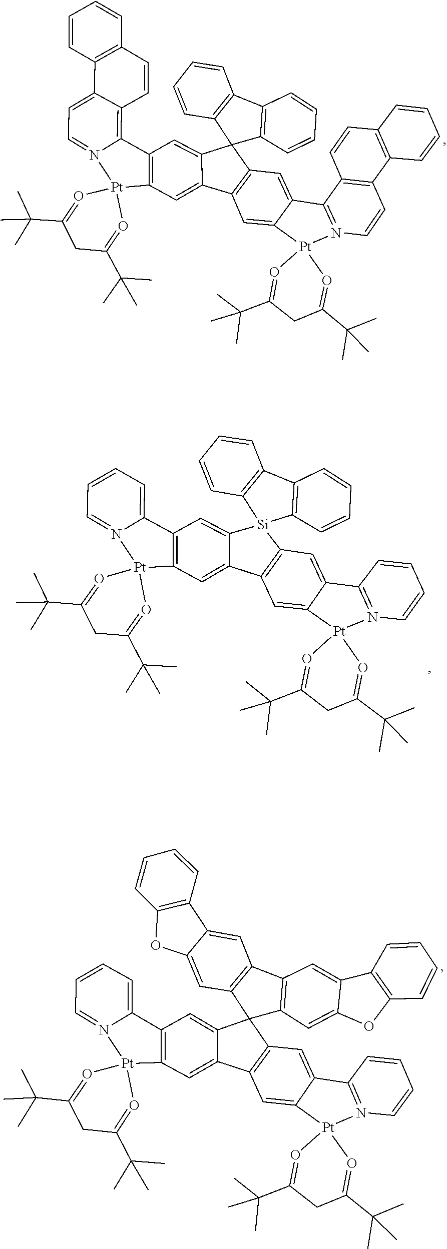

7. A light-emitting composition comprising:
the organometallic complex according to claim 1; and
a first compound different from the organometallic complex.

8. The light-emitting composition according to claim 7, wherein a concentration of the organometallic complex in terms of % by mass is 50% by mass or more and 100% by mass or less relative to the first organic compound.

9. The light-emitting composition according to claim 8, wherein the first organic compound is a liquid.

10. An organic light-emitting device comprising:
a first electrode;
a second electrode; and
an organic compound layer disposed between the first electrode and the second electrode,
wherein the organic compound layer contains the organometallic complex according to claim 1.

11. The organic light-emitting device according to claim 10,
wherein the organic compound layer contains the organometallic complex and a first organic compound different from the organometallic complex, and
the first organic compound has a lowest excited triplet energy equal to or larger than a lowest excited triplet energy of the organometallic complex.

12. The organic light-emitting device according to claim 11,
wherein the organic compound layer includes
a light-emitting layer,
a first charge transport layer disposed between the first electrode and the light-emitting layer, and
a second charge transport layer disposed between the second electrode and the light-emitting layer, and
the first charge transport layer has a lowest excited triplet energy larger than the lowest excited triplet energy of the first organic compound, and the second charge transport layer has a lowest excited triplet energy larger than the lowest excited triplet energy of the first organic compound.

13. A display apparatus comprising:
a plurality of pixels; and
a transistor connected to the plurality of pixels,
wherein at least one of the plurality of pixels is the organic light-emitting device according to claim 10.

14. An imaging apparatus comprising:
an optical unit including a plurality of lenses;
an imaging device configured to receive light that has passed through the optical unit; and
a display unit configured to display an image captured by the imaging device,
wherein the display unit includes the organic light-emitting device according to claim 10.

15. Electronic equipment comprising:
a display unit;
a housing provided with the display unit; and
a communication unit provided in the housing and configured to communicate with an external unit,
wherein the display unit includes the organic light-emitting device according to claim 10.

16. An illumination apparatus comprising:
a light source; and
a member configured to transmit light emitted from the light source,
wherein the light source includes the organic light-emitting device according to claim 10.

17. A moving object comprising:
a lighting fixture; and
a body provided with the lighting fixture,
wherein the lighting fixture includes the organic light-emitting device according to claim 10.
